(19) United States
(12) Patent Application Publication
(10) Pub. No.: US 2025/0273509 A1
(43) Pub. Date: Aug. 28, 2025

(54) SEMICONDUCTOR STRUCTURE WITH ETCH STOP LAYER AND METHOD FOR MAKING THE SAME

(71) Applicant: Peiching LING, Taipei (TW)

(72) Inventors: Peiching LING, San Jose, CA (US); Nanray WU, Miaoli (TW); Liang-Gi YAO, Hsinchu City (TW)

(21) Appl. No.: 18/857,838

(22) PCT Filed: Jul. 4, 2023
(86) PCT No.: PCT/US23/69597

§ 371 Date: Oct. 18, 2024

Related U.S. Application Data
(60) Provisional application No. 63/382,726, filed on Nov. 8, 2022.

(51) Int. Cl. H01L 21/762; H01L 23/544; H10D 86/00

(52) U.S. Cl. CPC H01L 21/76254; H01L 23/544; H10D 86/201; H01L 2223/54426

(57) ABSTRACT

The present disclosure relates to semiconductor structures, methods for making the same, and methods using the same. The semiconductor structure comprises a first substrate, a second substrate on the first substrate, a first bonding layer between the first substrate and the second substrate, a first etch stop layer between the first bonding layer and the second substrate, and the first etch stop layer has high etch selectivity against the first bonding layer. In particular, some embodiments of the present disclosure relate to semiconductor structures with etch stop layer, methods for making the same, and methods using the same.

### RELATED APPLICATION

This application claims priority to U.S. Provisional Patent Application Ser. No. 63/382,726, filed on Nov. 8, 2022, entitled “Structures and processes including an etch stop layer,” which is incorporated herein by reference in its entirety.

### BACKGROUND OF THE INVENTION

### Field of the Invention

The present disclosure relates to semiconductor structures, methods for making the same, and methods using the same. In particular, some embodiments of the present disclosure relate to semiconductor structures with etch stop layer, methods for making the same, and methods using the same.

### Description of Related Art

The semiconductor industry faces continuous demand for improvements in the integration density of various electronic components (i.e., transistors, diodes, resistors, capacitors, etc.). This improvement in integration density has come from repeated reduction in minimum feature size, allowing more components to be integrated into a given chip area. However, there are physical limitations to the limitations on the lithography process. On the other hand, while the dimension of the semiconductor devices is reduced and the integration density is increased, the space between these devices is decreased. The inter-device space becomes critical to the performance of the devices, and when the space is too small, these devices may interfere with each other. Therefore, compromise has to be made to balance the feature size and the inter-device space and the performance of each device may need to be optimized. Also, when more devices are put into one chip, circuit RC delay and power consumption may increase due to the significant gains in the number and length of interconnections between devices.

As the lateral dimensions of semiconductor devices become smaller in each technology generation, it faces a bottleneck to further increase the integration density. Generally speaking, the conventional fabrication of semiconductor devices is performed on the front side of the substrates, and through-substrate vias (TSVs) may need to be used to connect between the devices and/or interconnect structures. However, there is still a need to improve the manufacturing process for a higher integration density and better performance of the devices.

### SUMMARY

According to the present disclosure, a semiconductor structure is provided. The semiconductor structure comprises a first substrate, a second substrate, a first bonding layer, and a first etch stop layer. The second substrate is on the first substrate. The first bonding layer is between the first substrate and the second substrate. The first etch stop layer is between the first bonding layer and the second substrate. The first etch stop layer has high etch selectivity against the first bonding layer.

In one embodiment, the second substrate is made of silicon, germanium, silicon germanium, gallium arsenide (GaAs), indium phosphide (InP), silicon carbide (SiC), or gallium nitride (GaN).

In one embodiment, the first bonding layer comprises silicon oxide, and the first etch stop layer comprises silicon nitride, silicon oxynitride, doped semiconductor material, undoped semiconductor material, metal, or conductive metal compound.

In one embodiment, the first etch stop layer comprises a dielectric material.

In one embodiment, the first etch stop layer has an etch selectivity higher than 5:1 against the first bonding layer.

In one embodiment, the semiconductor structure further comprises a second etch stop layer between the first substrate and the first bonding layer. The second etch stop layer has high etch selectivity against the first substrate.

In one embodiment, the first substrate comprises single crystalline semiconductor material or glass, and the second etch stop layer comprises silicon nitride, silicon oxynitride, doped semiconductor material, undoped semiconductor material, metal, or conductive metal compound.

In one embodiment, the semiconductor structure further comprises an intermediate layer between the first etch stop layer and the second substrate.

In one embodiment, the intermediate layer comprises doped semiconductor material, metal, or conductive metal compound.

In one embodiment, the first etch stop layer comprises silicon nitride or silicon oxynitride.

In one embodiment, the intermediate layer is patterned.

In one embodiment, the intermediate layer comprises silicon oxide or high k material.

In one embodiment, the first etch stop layer comprises silicon nitride, silicon oxynitride, doped semiconductor material, metal, or conductive metal compound.

In one embodiment, the semiconductor structure further comprises an alignment mark disposed in the second substrate.

In one embodiment, the semiconductor structure further comprises a second etch stop layer and a second bonding layer. The second etch stop layer is between the first substrate and the first bonding layer. The second bonding layer is between the first substrate and the second etch stop layer. The second etch stop layer has high etch selectivity against the second bonding layer.

In one embodiment, the second bonding layer comprises silicon oxide, and the second etch stop layer comprises silicon nitride, silicon oxynitride, doped semiconductor material, undoped semiconductor material, metal, or conductive metal compound.

According to the present disclosure, a method for making a semiconductor structure is provided. The method comprises providing a first structure comprising a first substrate (step (a)). The method comprises providing a second structure comprising a second substrate and a first etch stop layer on the second substrate, and the second substrate comprises an implanted hydrogen layer (step (b)). The method comprises bonding the first structure and the second structure by a bonding layer to form a bonded structure (step (c)). The method comprises removing a portion of the second substrate from approximately the implanted hydrogen layer (step (d)).

In one embodiment, the second substrate is made of silicon, germanium, silicon germanium, gallium arsenide (GaAs), indium phosphide (InP), silicon carbide (SiC), or gallium nitride (GaN).

In one embodiment, the bonding layer comprises silicon oxide, and the first etch stop layer comprises silicon nitride, silicon oxynitride, doped semiconductor material, undoped semiconductor material, metal, or conductive metal compound.

In one embodiment, the step (b) comprises providing a second substrate (step (b1)), forming a first etch stop layer on the second substrate (step (b2)), and implanting a hydrogen layer into the second substrate (step (b3)).

In one embodiment, the step (c) comprises forming a first dielectric layer on the first substrate and forming a second dielectric layer on the first etch stop layer before bonding.

In one embodiment, the bonded structure further comprises a second etch stop layer between the first substrate and the bonding layer.

In one embodiment, the step (a) comprises providing a first substrate (step (a1)) and forming the second etch stop layer on the first substrate (step (a2)).

In one embodiment, the step (c) comprises forming a first dielectric layer on the second etch stop layer and forming a second dielectric layer on the first etch stop layer before bonding.

In one embodiment, the bonded structure further comprises an intermediate layer between the first etch stop layer and the second substrate.

In one embodiment, the step (b) comprises providing a second substrate (step (b1)), forming an intermediate layer on the second substrate (step (b2)), forming a first etch stop layer on the intermediate layer (step (b3)), and implanting a hydrogen layer into the second substrate (step (b4)).

In one embodiment, the step (b2) further comprises patterning the intermediate layer.

According to the present disclosure, a method for making a semiconductor device is provided. The method comprises providing a semiconductor structure comprising a first substrate, a second substrate on the first substrate, a bonding layer between the first substrate and the second substrate, and a first etch stop layer between the bonding layer and the second substrate (step (a)). The method comprises forming a first portion of the semiconductor device (step (b)). The method comprises adding a third substrate on a first side of the second substrate, and the second substrate is between the third substrate and the first substrate (step (c)). The method comprises removing the first substrate and the bonding layer of the semiconductor structure to expose the first etch stop layer (step (d)). The method comprises removing at least a portion of the first etch stop layer (step (c)).

In one embodiment, the first portion of the semiconductor device comprises a transistor or a diode.

In one embodiment, the step (b) comprises doping the second substrate or etching the second substrate.

In one embodiment, the method further comprises forming a second portion of the semiconductor device on a second side of the second substrate (step (f)).

In one embodiment, the first portion of the semiconductor device comprises a transistor comprising a source region, a drain region, a channel region, and a gate structure, and the second portion of the semiconductor device comprises a capacitor electrically connected to the source region of the transistor.

In one embodiment, the first portion of the semiconductor device comprises a transistor comprising a first source/drain region, a second source/drain region, a channel region, and a first gate structure, and the second portion of the semiconductor device comprises a second gate structure overlapped with the channel region of the transistor.

In one embodiment, the method further comprises forming a via on the second side of the second substrate, wherein the first gate structure is electrically connected to the second gate structure through the via.

In one embodiment, the method further comprises forming first interconnect structures on the first side of the second substrate before the step (c.

In one embodiment, the method further comprises forming second interconnect structures on a second side of the second substrate after the step (e).

In one embodiment, the semiconductor structure further comprises an intermediate layer between the first etch stop layer and the second substrate.

In one embodiment, the step (e) comprises removing at least a portion of the first etch stop layer to expose the intermediate layer.

In one embodiment, the intermediate layer is patterned.

In one embodiment, the step (d) comprises performing a first etching process by applying a first etchant.

In one embodiment, the step (e) comprises performing a second etching process by applying a second etchant.

In one embodiment, the semiconductor structure further comprises an alignment mark disposed in the second substrate.

### BRIEF DESCRIPTION OF THE DRAWINGS

FIG. 1 is a schematic view to illustrate an embodiment of a semiconductor structure according to the present disclosure.

FIG. 2 is a schematic view to illustrate an embodiment of a semiconductor structure according to the present disclosure.

FIG. 3 is a schematic view to illustrate an embodiment of a semiconductor structure according to the present disclosure.

FIG. 4 is a schematic view to illustrate an embodiment of a semiconductor structure according to the present disclosure.

FIG. 5 is a schematic view to illustrate an embodiment of a semiconductor structure according to the present disclosure.

FIG. 6 is a schematic view to illustrate an embodiment of a semiconductor structure according to the present disclosure.

FIG. 7 is a schematic view to illustrate an embodiment of a semiconductor structure according to the present disclosure.

FIGS. 8A to 8D are schematic diagrams illustrating intermediate stages in the manufacture of a semiconductor structure similar to the semiconductor structure shown in FIG. 1 according to one embodiment of the present disclosure.

FIGS. 9A to 9D are schematic diagrams illustrating intermediate stages in the manufacture of a semiconductor structure similar to the semiconductor structure shown in FIG. 2 according to one embodiment of the present disclosure.

FIGS. 10A to 10D are schematic diagrams illustrating intermediate stages in the manufacture of a semiconductor structure similar to the semiconductor structure shown in FIG. 4 according to one embodiment of the present disclosure.

FIGS. 11A to 110 are schematic diagrams illustrating intermediate stages in the manufacture of a semiconductor structure similar to the semiconductor structure shown in FIG. 5 according to one embodiment of the present disclosure.

FIGS. 12A to 12F are schematic diagrams illustrating intermediate stages in the manufacture of a semiconductor device according to one embodiment of the present disclosure.

FIGS. 13A to 13H are schematic diagrams illustrating intermediate stages in the manufacture of a semiconductor device according to one embodiment of the present disclosure.

FIG. 14 is a schematic diagram illustrating an intermediate stage in the manufacture of a semiconductor device according to one embodiment of the present disclosure.

FIGS. 15A to 15F are schematic diagrams illustrating intermediate stages in the manufacture of a semiconductor device according to one embodiment of the present disclosure.

FIG. 16 is a schematic diagram illustrating an intermediate stage in the manufacture of a semiconductor device according to one embodiment of the present disclosure.

FIGS. 17A to 17D are schematic diagrams illustrating intermediate stages in the manufacture of a semiconductor device according to one embodiment of the present disclosure.

FIGS. 18A to 18G are schematic diagrams illustrating intermediate stages in the manufacture of a semiconductor device according to one embodiment of the present disclosure.

FIG. 19 is a schematic diagram illustrating an intermediate stage in the manufacture of a semiconductor device according to one embodiment of the present disclosure.

FIG. 20 is a schematic diagram illustrating an intermediate stage in the manufacture of a semiconductor device according to one embodiment of the present disclosure.

### DETAILED DESCRIPTION OF PREFERRED EMBODIMENTS

The terminology used in the description presented below is intended to be interpreted in its broadest reasonable manner, even though it is used in conjunction with a detailed description of certain specific embodiments of the technology. Certain terms may even be emphasized below; however, any terminology intended to be interpreted in any restricted manner will be specifically defined as such in this Detailed Description section. Components and achievement of a semiconductor structure or device, according to the present disclosure may be illustrated in the following drawings and embodiments. However, the size and shape shown on drawings for the semiconductor structure or device do not limit the features of the present disclosure.

The phrase “on” used in this application can mean directly on or indirectly on with intervening elements or layers. The spatially relative terms, such as “beneath,” “below,” “lower,” “above,” “upper” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

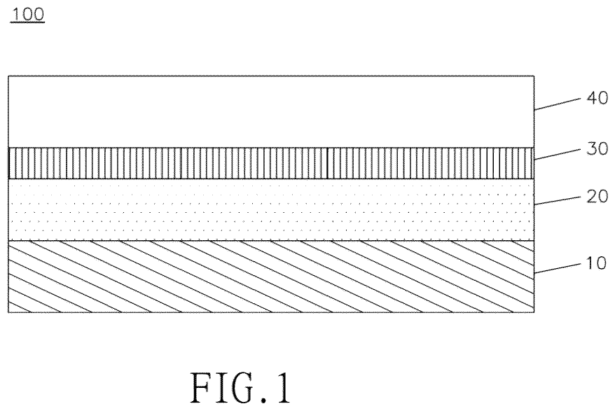

FIG. 1 is a schematic view to illustrate an embodiment of a semiconductor structure according to the present disclosure. As shown in FIG. 1, a semiconductor structure 100 comprises a first substrate 10, a second substrate 40 on the first substrate 10, a first bonding layer 20 between the first substrate 10 and the second substrate 40, and a first etch stop layer 30 between the first bonding layer 20 and the second substrate 40. The second substrate 40 of the semiconductor structure 100 may be used to fabricate various semiconductor devices including but not limited to a transistor, a diode, a capacitor, and/or a resistor.

In one embodiment, each of the first substrate 10 and the second substrate 40 is a wafer with a diameter of 6, 8, 12, or 18 inches. In this situation, the first substrate 10 may be referred to as a handle wafer and the second substrate 40 may be referred to as a device wafer. The first substrate 10 and the second substrate 40 may be a single crystalline semiconductor substrate, for example, made of silicon, germanium, silicon germanium, gallium arsenide (GaAs), indium phosphide (InP), silicon carbide (SiC), or gallium nitride (GaN). In other embodiments, the first substrate 10 may comprise glass, polysilicon, or ceramic. In one embodiment, the thickness of the second substrate 40 may be in a range between 5 nm and 0.2 μm. These values am merely examples and are not intended to be limiting.

The first etch stop layer 30 has high etch selectivity against the first bonding layer 20. An etch selectivity of the first etch stop layer 30 against the first bonding layer 20 may refer to the ratio of the etch rate of the first bonding layer 20 to the etch rate of the first etch stop layer 30 under the same etching condition, and the first etch stop layer 30 may have a high etch selectivity against the first bonding layer 20 when the etch rate of the first bonding layer 20 is substantially faster than the etch rate of the first etch stop layer 30 under the same etching condition. In some embodiments, the etch selectivity of the first etch stop layer 30 against the first bonding layer 20 may be higher than 5:1. In some embodiments, the etch selectivity of the first etch stop layer 30 against the first bonding layer 20 may be higher than 10:1, 20:1, 30:1, 50:1, 80:1, 100:1, 200:1, or 300:1.

For example, in one embodiment, the first etch stop layer 30 comprises silicon nitride and the first bonding layer 20 comprises silicon oxide. Under appropriate etching conditions, for example, dilute HF (e.g., a weight ratio of H₂O to HF at about 100:1) may be used as an etchant, the first etch stop layer 30 (e.g., silicon nitride) may have an etch rate of about 1 Å/min, and the first bonding layer 20 (e.g., silicon oxide) may have an etch rate of about 30 Å/min, which renders an etch selectivity of about 30:1 (oxide/nitride). The present disclosure is not limited thereto.

In some embodiments, other materials for the first etch stop layer 30 and the first bonding layer 20 may be used to achieve a high etch selectivity under proper etching conditions for dry etching processes or wet etching processes. Proper materials of the first etch stop layer and the first bonding layer and proper etching conditions can be selected based on actual needs and properties of the materials. With the arrangements disclosed herein, the embedded first etch stop layer, which may be formed in advance in the semiconductor structure, may substantially stop an etch of the bonding layer to protect the structures in the second substrate of the semiconductor structure. As such, the difficulty in fabricating semiconductor devices and/or interconnect structures on both sides of the second substrate may be reduced.

In some embodiments, the first bonding layer 20 comprises oxide such as silicon oxide, and the first etch stop layer 30 may comprise silicon nitride, silicon oxynitride, doped semiconductor material, undoped semiconductor material, metal, conductive metal compound, or combinations thereof. The doped semiconductor material may be semiconductor material with p-type dopants, such as boron, aluminum, gallium, indium, the like, or combinations thereof or semiconductor material with n-type dopants, such as phosphorus, arsenic, antimony, bismuth, the like, or combinations thereof. The undoped semiconductor material may be amorphous silicon, polysilicon, silicon germanium, the like, or combinations thereof. The metal may be aluminum, gold, copper, tungsten, the like, or an alloy thereof. The conductive metal compound may be metal silicide, metal carbide, metal nitride, the like, or combinations thereof, e.g., WN, TaN, TaSi, TiN, TiSi, TiSiN, TiAlN, MoN, IrOx, RuOx, or RuTiN.

In some embodiments, the first etch stop layer 30 comprises a dielectric material, such as silicon nitride, silicon oxynitride, the like, or a combination thereof. The disclosure is not limited thereto. As shown in FIG. 1, in some embodiments, the first etch stop layer 30 is in direct contact with the first bonding layer 20. As such, the first etch stop layer 30 may function as an etch stop layer under a removal process of the first bonding layer 20. However, in some embodiments, intervening layers (not shown) may be present between the first etch stop layer and the first bonding layer as long as the removal process of the first bonding layer 20 can stop at the first etch stop layer 30. In one embodiment, the thickness of the first bonding layer 20 may be in a range between 0.2 nm and 1000 nm. In one embodiment, the thickness of the first etch stop layer 30 may be in a range between 0.2 nm and 5 nm. These values are merely examples and are not intended to be limiting.

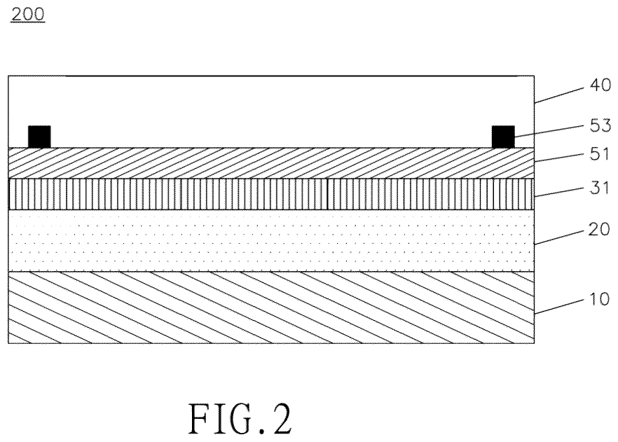

FIG. 2 is a schematic view to illustrate an embodiment of a semiconductor structure according to the present disclosure. As shown in FIG. 2, a semiconductor structure 200 may be substantially similar to the semiconductor structure 100 in FIG. 1 where like reference numerals indicate like elements. The semiconductor structure 200 comprises a first substrate 10, a second substrate 40 on the first substrate 10, a first bonding layer 20 between the first substrate 10 and the second substrate 40, a first etch stop layer 31 between the first bonding layer 20 and the second substrate 40, and an intermediate layer 51 between the first etch stop layer 31 and the second substrate 40.

The first etch stop layer 31 may be substantially similar to the first etch stop layer 30 in FIG. 1, for example, the first etch stop layer 31 has high etch selectivity against the first bonding layer 20. In some embodiments, the etch selectivity of the first etch stop layer 31 against the first bonding layer 20 may be higher than 5:1. In some embodiments, the etch selectivity of the first etch stop layer 31 against the first bonding layer 20 may be higher than 10:1, 20:1, 30:1, 50:1, 80:1, 100:1, 200:1, or 300:1. All other descriptions about semiconductor structure 100 may apply here if applicable.

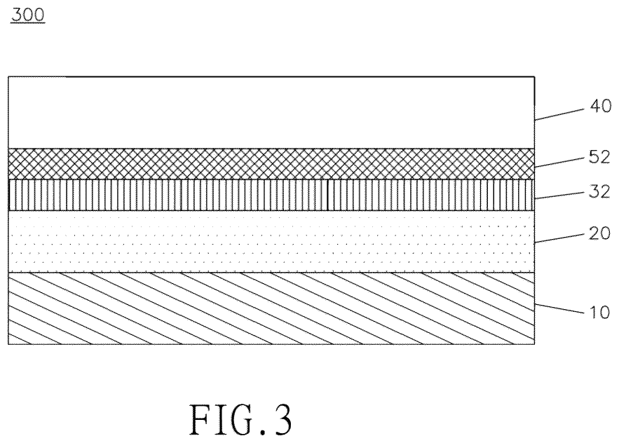

In some embodiments, the intermediate layer 51 comprises doped semiconductor material, metal, conductive metal compound, or combinations thereof. In such embodiments, the first etch stop layer 31 may comprise silicon nitride or silicon oxynitride, however, the present disclosure is not limited thereto. In one embodiment, the thickness of the intermediate layer 51 may be in a range between 10 nm and 200 nm. In one embodiment, the thickness of the first etch stop layer 31 may be in a range between 0.2 nm and 5 nm. These values are merely examples and are not intended to be limiting. The intermediate layer may be conductive or may include a conductive sublayer as the intermediate layer 51 of the semiconductor structure 200 shown in FIG. 2. However, the intermediate layer may be non-conductive as the intermediate layer 52 of the semiconductor structure 300 shown in FIG. 3. In some embodiments, the intermediate layer 51 may be patterned. The patterned conductive layer pre-formed in the intermediate layer 51 of the semiconductor structure 200 may have various applications for different fabrication purposes. For example, a portion of a device or element(s) function with a device may be formed or partially formed in the intermediate layer 51. In some embodiments, the intermediate layer 51 may include a stack of sublayers, which may include at least one patterned conductive sublayer comprising doped semiconductor material, metal, and/or conductive metal compound as described above that may be formed into a portion of a device or element(s) function with a device. In some embodiments, one or more of the sublayer(s) of the intermediate layer or an extra layer may be disposed between such patterned conductive sublayer and the second substrate. However, in some embodiments, such patterned conductive sublayer may be in contact with the second substrate depending on actual needs. In some embodiments, the patterned intermediate layer 51 or the patterned conductive sublayer may be electrically coupled to a semiconductor device that is formed or will be subsequently formed in the second substrate 40. The pre-formed portion or element(s) and/or the sublayer(s) on which the portion or element(s) are disposed on may be formed to have better contact with each other and/or better contact with the second substrate.

In one embodiment, the semiconductor structure 200 may further comprise an alignment mark 53 disposed in the second substrate 40. The patterning process of the intermediate layer 51, the fabrication of devices in the second substrate 40, and/or the fabrication of features above and/or below the second substrate 40 may be conducted according to the alignment mark 53. As such, the introduce of the alignment mark may further reduce the difficulty in fabricating semiconductor devices or interconnect structures on both sides of the second substrate.

FIG. 3 is a schematic view to illustrate an embodiment of a semiconductor structure according to the present disclosure. As shown in FIG. 3, a semiconductor structure 300 may be substantially similar to the semiconductor structure 200 in FIG. 2 where like reference numerals indicate like elements. The semiconductor structure 300 comprises a first substrate 10, a second substrate 40 on the first substrate 10, a first bonding layer 20 between the first substrate 10 and the second substrate 40, a first etch stop layer 32 between the first bonding layer 20 and the second substrate 40, and an intermediate layer 52 between the first etch stop layer 32 and the second substrate 40.

The first etch stop layer 32 may be substantially similar to the first etch stop layer 30 in FIG. 1, for example, the first etch stop layer 32 has high etch selectivity against the first bonding layer 20. In some embodiments, the etch selectivity of the first etch stop layer 32 against the first bonding layer 20 may be higher than 5:1. In some embodiments, the etch selectivity of the first etch stop layer 32 against the first bonding layer 20 may be higher than 10:1, 20:1, 30:1, 50:1, 80:1, 100:1, 200:1, or 300:1. All other descriptions about semiconductor structures 100 and 200 may apply here if applicable.

In the embodiment shown in FIG. 3, the intermediate layer 52 may comprise silicon oxide, high dielectric constant (high k) material, including but not limited to hafnium silicate, zirconium silicate, hafnium dioxide, and zirconium dioxide, or combinations thereof. In one embodiment, the thickness of the intermediate layer 52 may be in a range between 10 nm and 200 nm. The first etch stop layer 32 may comprise silicon nitride, silicon oxynitride, doped semiconductor material, metal, conductive metal compound, or combinations thereof. In one embodiment, the thickness of the first etch stop layer 32 may be in a range between 0.2 nm and 5 nm. These values are merely examples and are not intended to be limiting. The intermediate layer 52 may be patterned or un-patterned. The patterned or un-patterned layer intermediate layer 52 of the semiconductor structure 300 may have various applications for different fabrication purposes. For example, the intermediate layer 52 may be formed into a gate dielectric layer. The pre-formed dielectric layer in the intermediate layer 52 may have better quality and may have better contact with the second substrate 40.

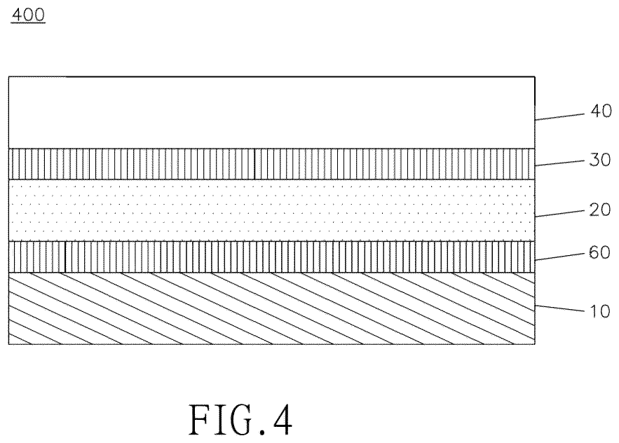

FIG. 4 is a schematic view to illustrate an embodiment of a semiconductor structure according to the present disclosure. As shown in FIG. 4, a semiconductor structure 400 may be substantially similar to the semiconductor structure 100 in FIG. 1 where like reference numerals indicate like elements. The semiconductor structure 400 comprises a first substrate 10, a second substrate 40 on the first substrate 10, a first bonding layer 20 between the first substrate 10 and the second substrate 40, a first etch stop layer 30 between the first bonding layer 20 and the second substrate 40, and a second etch stop layer 60 between the first substrate 10 and the first bonding layer 20.

The second etch stop layer 60 may have high etch selectivity against the first substrate 10, such that the etch rate of the first substrate 10 is substantially faster than the etch rate of the second etch stop layer 60 under the same etching condition. In some embodiments, the etch selectivity of the second etch stop layer 60 against the first substrate 10 may be higher than 5:1. In some embodiments, the etch selectivity of the second etch stop layer 60 against the first substrate 10 may be higher than 10:1, 20:1, 30:1, 50:1, 80:1, 100:1, 200:1, or 300:1. Proper materials of the second etch stop layer and the first substrate and proper etching conditions can be selected based on actual needs and properties of the materials. All other descriptions about semiconductor structure 100 may apply here if applicable. With such arrangements, the embedded second etch stop layer, which may be formed in advance in the semiconductor structure, may substantially stop an etch of the first substrate to protect the structures underneath and to provide various manufacturing options.

In some embodiments, the first substrate 10 may comprise single crystalline semiconductor material or glass, and the second etch stop layer 60 may comprise silicon nitride, silicon oxynitride, doped semiconductor material, undoped semiconductor material, metal, conductive metal compound, or combinations thereof. In one embodiment, the second etch stop layer 60 may comprise a material or a combination of materials different from the first etch stop layer 30. In one embodiment, the thickness of the second etch stop layer 60 may be in a range between 0.2 nm and 5 nm. These values are merely examples and are not intended to be limiting.

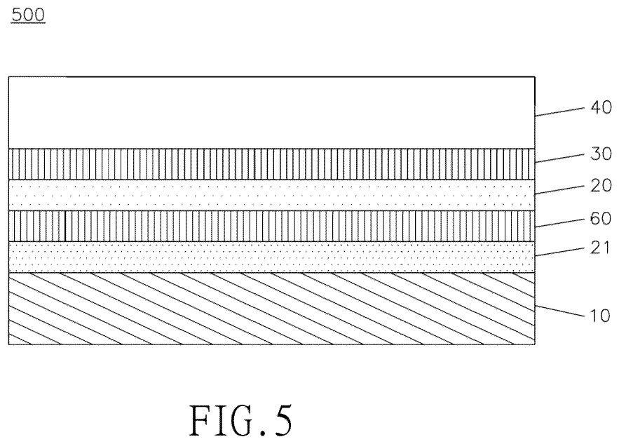

FIG. 5 is a schematic view to illustrate an embodiment of a semiconductor structure according to the present disclosure. As shown in FIG. 5, a semiconductor structure 500 may be substantially similar to the semiconductor structure 100 in FIG. 1 where like reference numerals indicate like elements. The semiconductor structure 500 further comprises a second etch stop layer 60 between the first substrate 10 and the first bonding layer 20, and a second bonding layer 21 between the first substrate 10 and the second etch stop layer 60.

The second etch stop layer 60 may have high etch selectivity against the second bonding layer 21, such that the etch rate of the second bonding layer 21 is substantially faster than the etch rate of the second etch stop layer 60 under the same etching condition. In some embodiments, the etch selectivity of the second etch stop layer 60 against the second bonding layer 21 may be higher than 5:1. In some embodiments, the etch selectivity of the second etch stop layer 60 against the second bonding layer 21 may be higher than 10:1, 20:1, 30:1, 50:1, 80:1, 100:1, 200:1, or 300:1. Proper materials of the second etch stop layer and the second bonding layer and proper etching conditions can be selected based on actual needs and properties of the materials. All other descriptions about semiconductor structure 100 may apply here if applicable. With such arrangements, the embedded second etch stop layer, which may be formed in advance in the semiconductor structure, may substantially stop an etch of the second bonding layer to protect the structures underneath and to provide various manufacturing options.

In some embodiments, the second bonding layer 21 may comprise oxide such as silicon oxide, and the second etch stop layer 60 may comprise silicon nitride, silicon oxynitride, doped semiconductor material, undoped semiconductor material, metal, conductive metal compound, or combinations thereof. In one embodiment, the thickness of the second bonding layer 21 may be in a range between 0.2 nm and 1000 nm. In one embodiment, the thickness of the second etch stop layer 60 may be in a range between 0.2 nm and 5 nm. These values are merely examples and am not intended to be limiting.

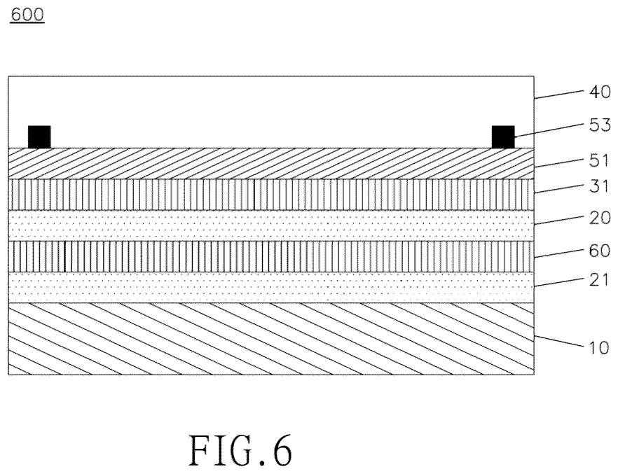

FIG. 6 is a schematic view to illustrate an embodiment of a semiconductor structure according to the present disclosure. As shown in FIG. 6, a semiconductor structure 600 may be substantially similar to the semiconductor structure 200 in FIG. 2 where like reference numerals indicate like elements. The semiconductor structure 60 further comprises a second etch stop layer 60 between the first substrate 10 and the first bonding layer 20, and a second bonding layer 21 between the first substrate 10 and the second etch stop layer 60. The second etch stop layer 60 of the semiconductor structure 600 may be similar to the second etch stop layer 60 of the semiconductor structure 500 described above with reference to FIG. 5. All other descriptions about semiconductor structures 200 and 500 may apply here if applicable.

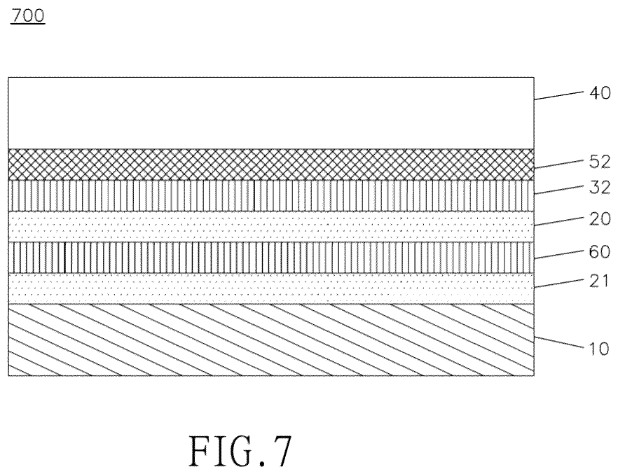

FIG. 7 is a schematic view to illustrate an embodiment of a semiconductor structure according to the present disclosure. As shown in FIG. 7, a semiconductor structure 700 may be substantially similar to the semiconductor structure 300 in FIG. 3 where like reference numerals indicate like elements. The semiconductor structure 700 further comprises a second etch stop layer 60 between the first substrate 10 and the first bonding layer 20, and a second bonding layer 21 between the first substrate 10 and the second etch stop layer 60. The second etch stop layer 60 of the semiconductor structure 700 may be similar to the second etch stop layer 60 of the semiconductor structure 500 described above with reference to FIG. 5. All other descriptions about semiconductor structures 300 and 500 may apply here if applicable.

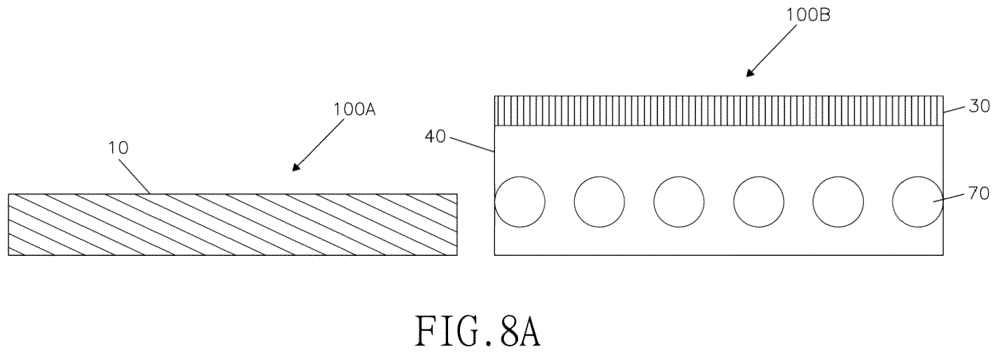

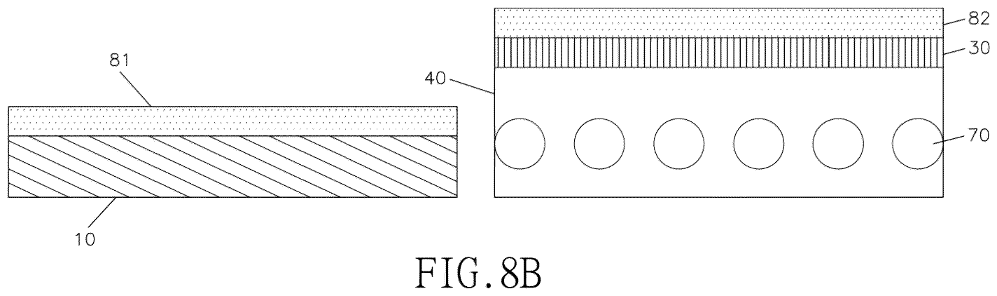

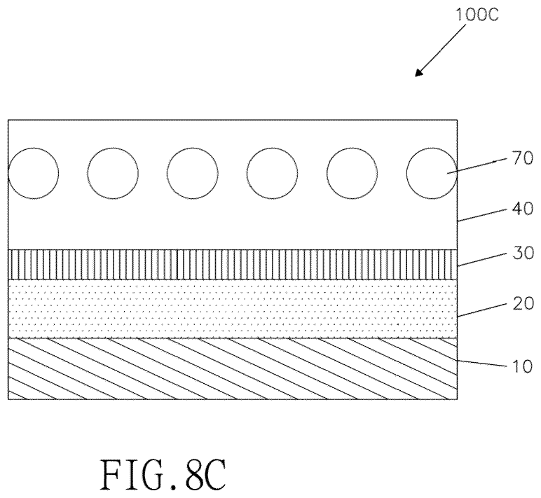

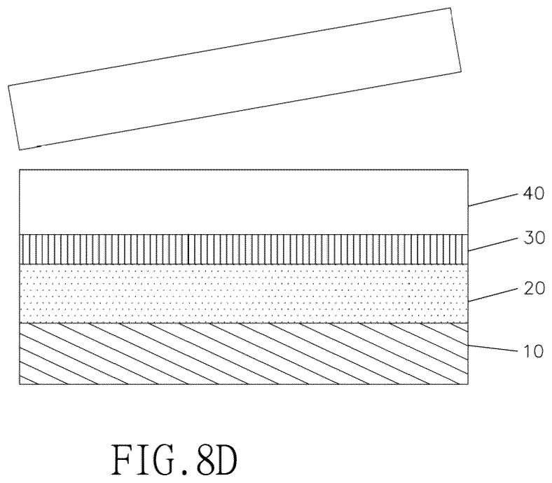

FIGS. 8A to 8D are schematic diagrams illustrating intermediate stages in the manufacture of a semiconductor structure similar to the semiconductor structure shown in FIG. 1 according to one embodiment of the present disclosure.

As shown in FIG. 8A, a first structure 100A and a second structure 100B are provided. The first structure 100A comprises a first substrate 10. The second structure 100B comprises a second substrate 40 with an implanted hydrogen layer 70 inside the second substrate 40 and a first etch stop layer 30 on the second substrate 40. As described before, the first substrate 10 and the second substrate 40 may be a single crystalline semiconductor substrate, for example, made of silicon, germanium, silicon germanium, gallium arsenide (GaAs), indium phosphide (InP), silicon carbide (SiC), or gallium nitride (GaN). In other embodiments, the first substrate 11) may comprise glass, polysilicon, or ceramic.

The first etch stop layer 30 may comprise silicon nitride, silicon oxynitride, doped semiconductor material, undoped semiconductor material, metal, conductive metal compound, or combinations thereof, similar to the first etch stop layer 30 described above with respect to FIG. 1. The thickness of the first etch stop layer 30 may be in a range between 0.2 nm and 5 nm. These values are merely examples and are not intended to be limiting. The first etch stop layer 30 may be formed on the second substrate 40. In one embodiment, the first etch stop layer 30 is formed by epitaxial growth or by deposition such as chemical vapor deposition (CVD), physical vapor deposition (PVD), or atomic layer deposition (ALD). In one embodiment, the first etch stop layer 30 is formed by sputtering or evaporation.

The implanted hydrogen layer 70 is implanted inside the second substrate 40 at a certain depth before the bonding of the first structure 100A and the second structure 100B. The implantation may be conducted before or after the formation of the first etch stop layer 30 as long as the implanted hydrogen layer 70 will not be damaged by the succeeding processes. For example, if the formation of the first etch stop layer 30 requires high temperature, the hydrogen probably should be implanted after the formation of the first etch stop layer 30. In one embodiment, hydrogen ions are implanted into the second substrate 40 using a dosage of 10¹⁶ to 2×10¹⁷ ions/cm² at an implantation energy of 50 to 150 KeV. A larger dosage can be used with larger substrates. The implanted hydrogen layer 70 may be formed at a depth of about 4×10⁻⁵ to 8×10⁻⁵ inch (1 to 2 μm) from the top surface of the second substrate 40. These values are merely examples and are not intended to be limiting. In one embodiment, since the thicknesses of the first etch stop layer 30 and the second dielectric layer 82 are known, the proper implantation voltage can be selected to have the peak of the implanted hydrogen occur at the desired depth below the first etch stop layer 30. In one embodiment, when the first etch stop layer 30 comprises a metal, the implantation may be conducted before the formation of the first etch stop layer 30.

As shown in FIG. 8B, a first dielectric layer 81 is formed on the first substrate 10, and a second dielectric layer 82 is formed on the first etch stop layer 30 before the bonding of the first structure 100A and the second structure 100B. In one embodiment, only one of the first dielectric layer 81 and the second dielectric layer 82 is formed before the bonding of the first structure 100A and the second structure 100B. In one embodiment, the first dielectric layer 81 and/or the second dielectric layer 82 is formed by thermal oxidation or deposition such as CVD, PVD, or ALD. In some emoluments, the first dielectric layer 81 and/or the second dielectric layer 82 comprises silicon oxide. In some embodiments, the implantation for the formation of the implanted hydrogen layer 70 may be conducted after the formation of the second dielectric layer 82.

As shown in FIG. 8C, the second structure 100B is flipped and bonded onto the first structure 100A by the first bonding layer 20 to form a bonded structure 100C. For example, the second structure 100B may be bonded to the first structure 100A by a fusion bonding process, such as a hydrophilic fusion bonding process. In one embodiment, both the first dielectric layer 81 and the second dielectric layer 82 are cleaned by conventional cleaning techniques such as the RCA wafer cleaning procedure. The cleaning process removes surface impurities and particles from the surfaces of the dielectric layers 81 and 82. In one embodiment, hydroxyl groups (OH⁻) are formed on the surfaces to be bonded due to the presence of electric charges of atoms. Hydrogen bonds may be formed between the first dielectric layer 81 and the second dielectric layer 82 and an annealing process to form chemical bonds (e.g., Si—O bond) between the surfaces of the first dielectric layer 81 and the second dielectric layer 82 may be performed.

In the embodiment shown in FIG. 8C, the first dielectric layer 81 and the second dielectric layer 82 are bonded to form the first bonding layer 20. In some embodiments, when only one of the first dielectric layer and the second dielectric layer is formed before the bonding of the first structure 100A and the second structure 100B, the one of the first dielectric layer 81 and the second dielectric layer 82 forms the first bonding layer 20 of the bonded structure 100C. In one embodiment, the thickness of the first bonding layer 20 may be in a range between 0.2 nm and 1000 nm. These values are merely examples and are not intended to be limiting.

As shown in FIG. 8D, a portion of the second substrate 40 is removed from the bonded structure 100C at approximately the implanted hydrogen layer 70. The portion of the second substrate 40 may be removed by heating the bonded structure 100C at a first temperature. A first temperature is usually below 400° C. to avoid any damage to the semiconductor device fabricated in the second substrate 40 if there is any. In some embodiments, a portion of the second substrate 40 may be removed by other methods, as long as the portion of the second substrate 40 has been sufficiently weakened by previous hydrogen implantation and some subsequent annealing. For example, the bonded structure 100C can be cleaved by applying mechanical pressure to the second substrate 40 or by dipping and quenching the bonded structure 100C in liquid nitrogen.

The portion of the second substrate 40 remaining on the bonded structure 100C may be less than 3 μm based on the implanted depth of the implanted hydrogen layer 70. The thickness of the remaining portion of the second substrate 40 may also depend on the semiconductor manufacturing technology nodes applied for the fabrication of various semiconductor devices. After removal, the separated surface of the second substrate 40 usually has a roughness on the order of a few hundred angstroms. Such a separated surface of the second structure 40 may be polished by chemical mechanical polishing (CMP) to planarize and minimize the non-uniformity of the separated surface. Other approaches such as etching may be used for the same purpose. Another etch stop layer may need to be deposited in advance when etching is used to planarize and minimize the non-uniformity of the separated surface of the second substrate 40.

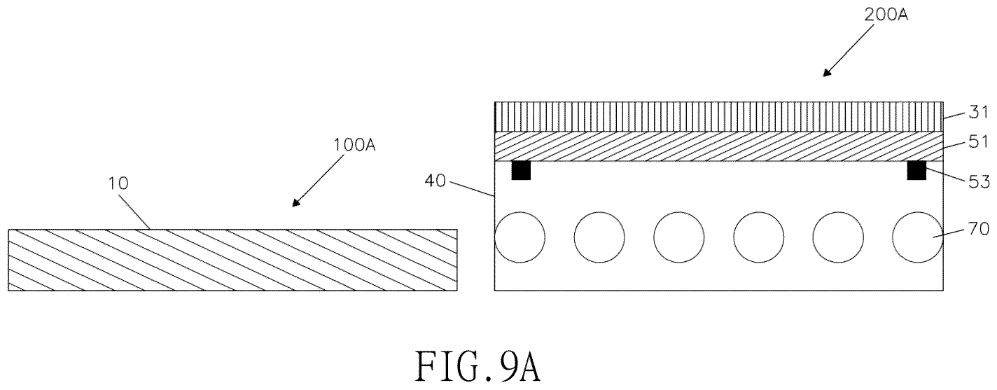

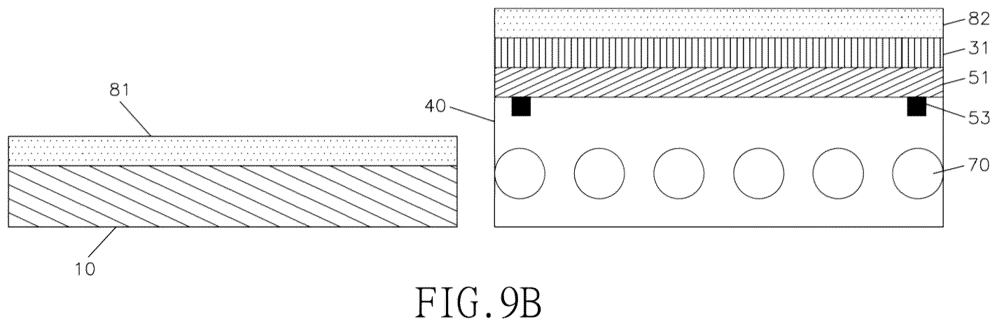

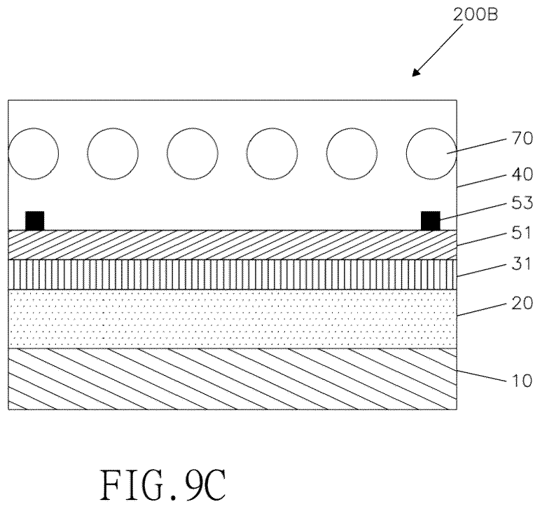

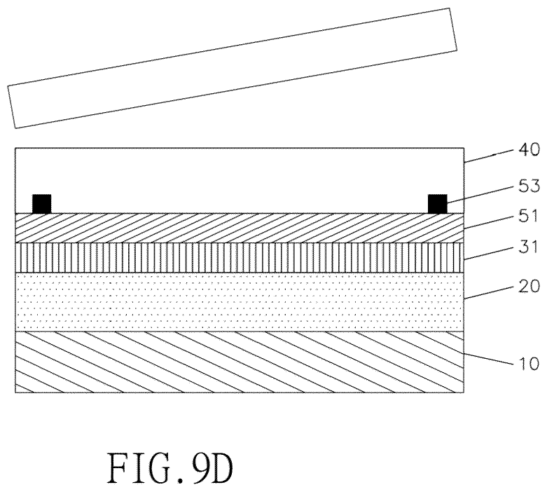

FIGS. 9A to 9D are schematic diagrams illustrating intermediate stages in the manufacture of a semiconductor structure similar to the semiconductor structure shown in FIG. 2 according to one embodiment of the present disclosure.

As shown in FIG. 9A, a first structure 100A and a second structure 200A are provided. The first structure 100A comprises a first substrate 10. The second structure 200A comprises a second substrate 40 with an implanted hydrogen layer 70 inside the second substrate 40, an intermediate layer 51 on the second substrate 40, and a first etch stop layer 31 on the intermediate layer 51. As described before, the intermediate layer 51 may comprise doped semiconductor material, metal, conductive metal compound, or combinations thereof, and the first etch stop layer 31 may comprise silicon nitride, silicon oxynitride, or combinations thereof. In one embodiment, the thickness of the intermediate layer 51 may be in a range between 10 nm and 200 nm. In one embodiment, the thickness of the first etch stop layer 31 may be in a range between 0.2 nm and 5 nm. These values are merely examples and are not intended to be limiting. The intermediate layer 51 may be formed on the second substrate 40. The first etch stop layer 31 may be formed on the intermediate layer 51. In one embodiment, the intermediate layer 51 and/or the first etch stop layer 31 is formed by epitaxial growth or by deposition such as CVD, PVD, or ALD. In one embodiment, the intermediate layer 51 and/or the first etch stop layer 31 is formed by sputtering or evaporation.

In some embodiments, depending on actual applications and circuit design, the intermediate layer 51 may be formed as a patterned layer before bonding the second structure 200A onto the first structure 100A. The patterned intermediate layer may be made through any suitable process (e.g., photolithography and etch process, damascene process, dual damascene process, or the like). In some embodiments, dielectric materials may be deposited on the second substrate 40. Trenches may then be formed in the dielectric material layer using suitable photolithography and etching techniques. For example, photosensitive material (photoresist) is disposed over the dielectric material layer and is selectively removed. An etch process, using the masking element formed of the photoresist, etches away portions of the dielectric layer thereby forming trenches. A subsequent deposition of conductive materials may be performed to fill the trenches to form the patterned intermediate layer. Such process may be repeated to form a plurality of sublayers of the intermediate layer, wherein each of the sublayers may be of the same or different patterns. The patterned intermediate layer may provide routing and layout having better contact with the second substrate.

In one embodiment, the second structure 200A may further comprise an alignment mark 53 disposed in the second substrate 40. The alignment mark 53 may be fabricated by suitable methods known in the art. The patterning process of the intermediate layer 51, the subsequent fabrication of semiconductor devices and/or conductive feature in the second substrate 40 and/or over the second substrate 40 may be performed according to the alignment mark 53. By using the same alignment mark 53 for the processing of the intermediate layer 51 and the fabrication of semiconductor devices and/or conductive feature, the manufacturing semiconductor devices and/or interconnect structures on both sides of the second substrate 40 can be achieved. In some embodiments, a portion of the layer (e.g. the intermediate layer and/or sublayer(s) thereof) on the alignment mark 53 may need to be removed to expose the alignment mark 53.

The implanted hydrogen layer 70 is implanted inside the second substrate 40 at a certain depth before the bonding of the first structure 100A and the second structure 200A. Similarly, the implantation may be conducted before or after the formation of the intermediate layer 51, the first etch stop layer 31, or the second dielectric layer 82 (as described below in FIG. 9B) as long as the implanted hydrogen layer 70 will not be damaged by the succeeding processes. The implantation process and the related details described before may apply here.

As shown in FIG. 9B, a first dielectric layer 81 is formed on the first substrate 10, and a second dielectric layer 82 is formed on the first etch stop layer 31 before the bonding of the first structure 100A and the second structure 200A. In one embodiment, only one of the first dielectric layer 81 and the second dielectric layer 82 is formed before the bonding of the first structure 100A and the second structure 200A. The formation of the dielectric layers 81 and 82 and the related details described before may apply here.

As shown in FIG. 9C, the second structure 200A is flipped and bonded onto the first structure 100A by the first bonding layer 20 to form a bonded structure 200B. The bonding process and related details described before may apply here.

As shown in FIG. 9D, a portion of the second substrate 40 is removed from the bonded structure 200B at approximately the implanted hydrogen layer 70. The removal process and the related details described before may apply here.

The various intermediate stages of forming the semiconductor structure similar to the semiconductor structure shown in FIG. 3 may be substantially similar to the processes described above with respect to FIGS. 9A to 9D. For example, the intermediate layer 51 and the first etch stop layer 31 are replaced with the intermediate layer 52 and the first etch stop layer 32, respectively. As described before, the intermediate layer 52 may comprise silicon oxide, high k material, including but not limited to hafnium silicate, zirconium silicate, hafnium dioxide, and zirconium dioxide, or combinations thereof. In one embodiment, the thickness of the intermediate layer 52 may be in a range between 10 nm and 200 nm. The first etch stop layer 32 comprises silicon nitride, silicon oxynitride, doped semiconductor material, metal, conductive metal compound, or combinations thereof. In one embodiment, the thickness of the first etch stop layer 32 may be in a range between 0.2 nm and 5 nm. These values are merely examples and are not intended to be limiting. The intermediate layer 52 may be formed on the second substrate 40. The first etch stop layer 32 may be formed on the intermediate layer 52. In one embodiment, the intermediate layer 52 and/or the first etch stop layer 32 is formed by epitaxial growth or by deposition such as CVD, PVD, or ALD. In one embodiment, the intermediate layer 52 and/or the first etch stop layer 32 is formed by sputtering or evaporation. The processes and the related details described before with respect to FIGS. 9A to 9D may apply here.

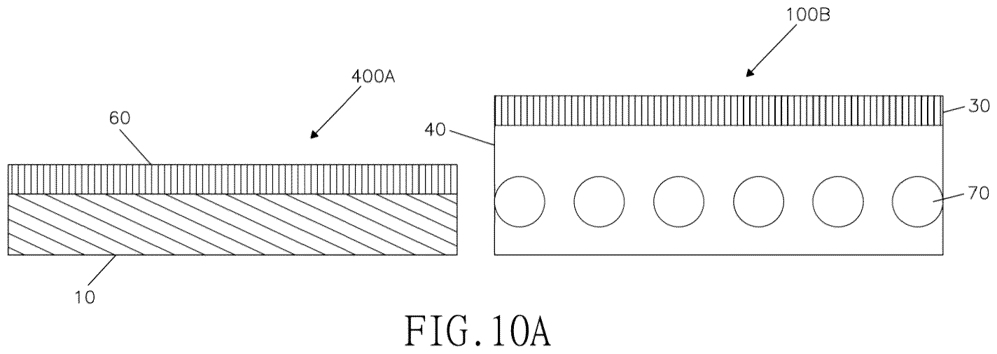

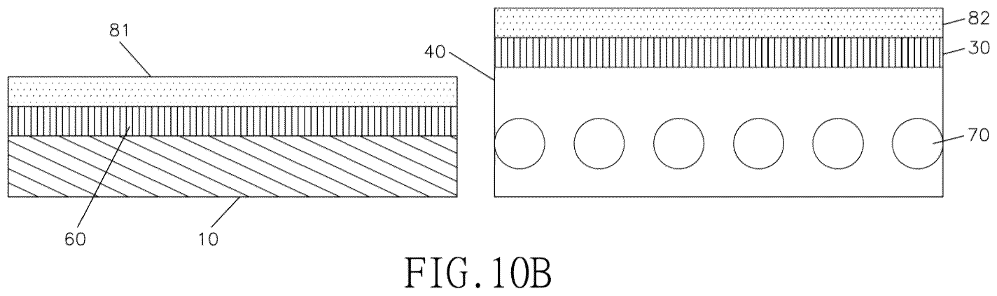

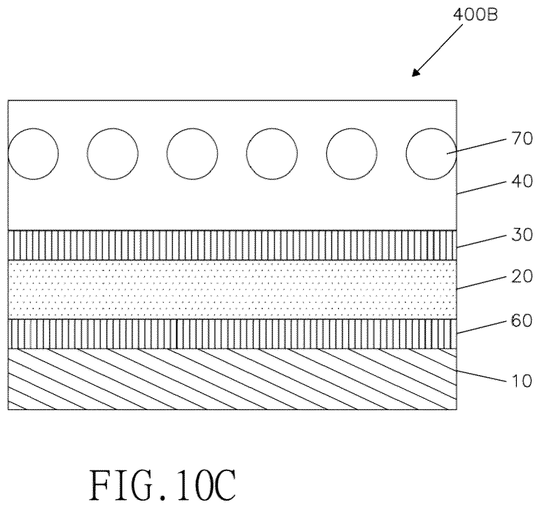

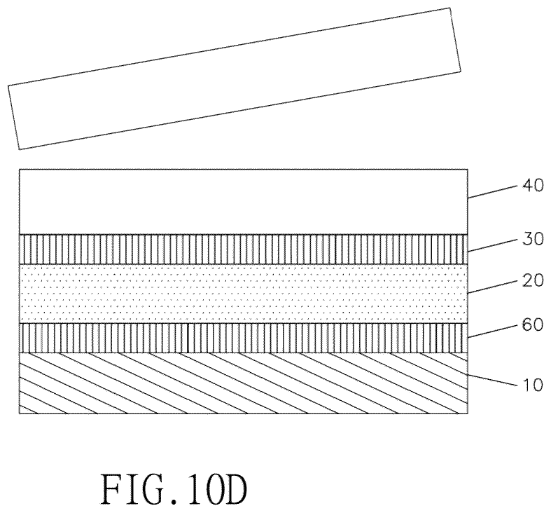

FIGS. 10A to 10D are schematic diagrams illustrating intermediate stages in the manufacture of a semiconductor structure similar to the semiconductor structure shown in FIG. 4 according to one embodiment of the present disclosure.

As shown in FIG. 10A, a first structure 400A and a second structure 100B are provided. The first structure 400A comprises a first substrate 10 and a second etch stop layer 60 on the first substrate 10. The second structure 100B comprises a second substrate 40 with an implanted hydrogen layer 70 inside the second substrate 40 and a first etch stop layer 30 on the second substrate 40. As described before, the second etch stop layer 60 may comprise silicon nitride, silicon oxynitride, doped semiconductor material, undoped semiconductor material, metal, conductive metal compound, or combinations thereof. In one embodiment, the second etch stop layer 60 may comprise a material or a combination of materials different from the first etch stop layer 30. In one embodiment, the thickness of the second etch stop layer 60 may be in a range between 0.2 nm and 5 nm. These values are merely examples and are not intended to be limiting. The second etch stop layer 60 may be formed on the first substrate 10. In one embodiment, the second etch stop layer 60 is formed by epitaxial growth or by deposition such as CVD, PVD, or ALD. In one embodiment, the second etch stop layer 60 is formed by sputtering or evaporation. The fabrication and related details of the second structure 100B described before may apply here.

As shown in FIG. 10B, a first dielectric layer 81 is formed on the second etch stop layer 60, and a second dielectric layer 82 is formed on the first etch stop layer 30 before the bonding of the first structure 400A and the second structure 100B. In one embodiment, only one of the first dielectric layer 81 and the second dielectric layer 82 is formed before the bonding of the first structure 400A and the second structure 100B. In one embodiment, the first dielectric layer 81 and/or the second dielectric layer 82 is formed by thermal oxidation or deposition such as CVD, PVD, or ALD. In some embodiments, the first dielectric layer 81 and/or the second dielectric layer 82 comprises silicon oxide.

As shown in FIG. 10C, the second structure 100B is flipped and bonded onto the first structure 400A by the first bonding layer 20 to form a bonded structure 400B. The bonding process and related details described before may apply here.

As shown in FIG. 10D, a portion of the second substrate 40 is removed from the bonded structure 4008 at approximately the implanted hydrogen layer 70. The removal process and the related details described before may apply here.

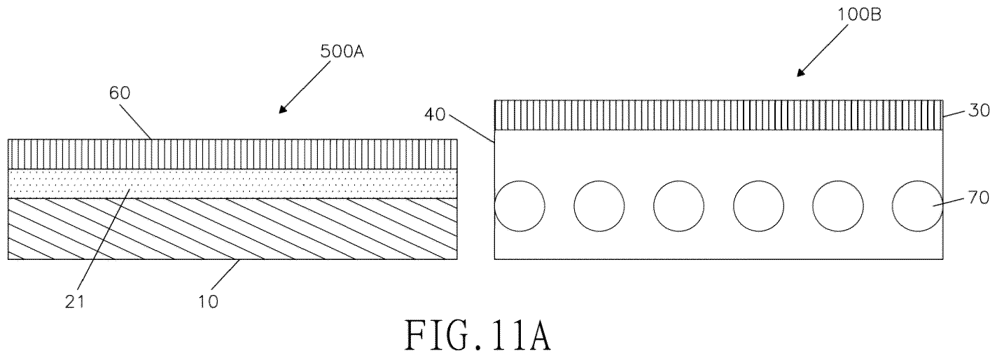

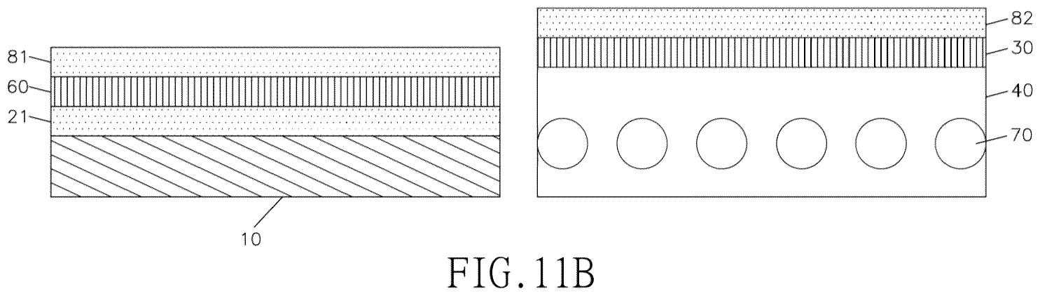

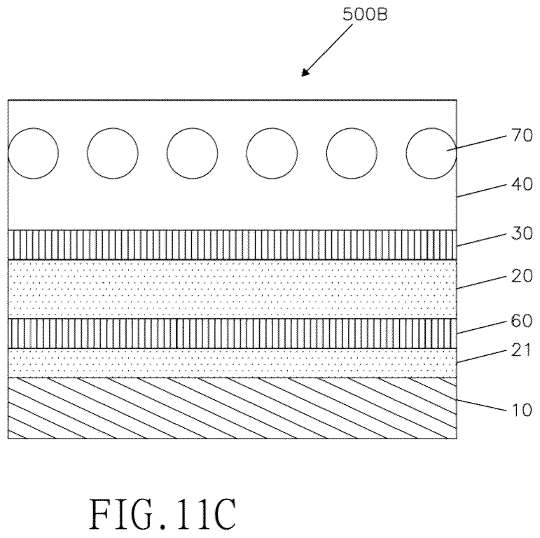

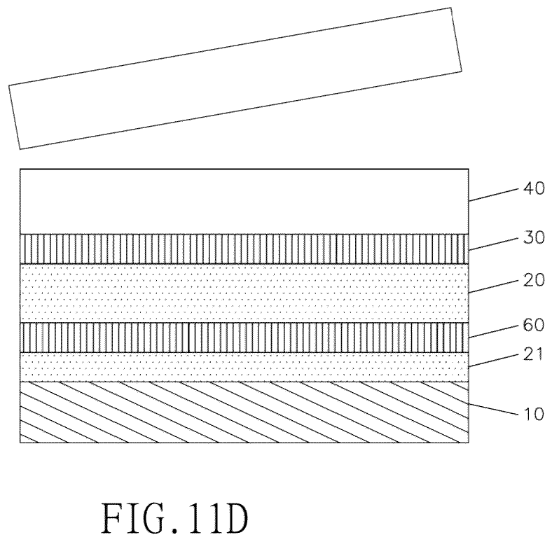

FIGS. 11A to 11D are schematic diagrams illustrating intermediate stages in the manufacture of a semiconductor structure similar to the semiconductor structure shown in FIG. 5 according to one embodiment of the present disclosure.

As shown in FIG. 11A, a first structure 500A and a second structure 100B are provided. The first structure 500A comprises a first substrate 10, a second bonding layer 21 on the first substrate 10, and a second etch stop layer 60 on the second bonding layer 21. The second structure 100B comprises a second substrate 40 with an implanted hydrogen layer 70 inside the second substrate 40 and a first etch stop layer 30 on the second substrate 40. As described before, the second bonding layer 21 may comprise oxide such as silicon oxide, and the second etch stop layer 60 may comprise silicon nitride, silicon oxynitride, doped semiconductor material, undoped semiconductor material, metal, conductive metal compound, or combinations thereof. In one embodiment, the thickness of the second bonding layer 21 may be in a range between 0.2 nm and 1000 nm. In one embodiment, the thickness of the second etch stop layer 60 may be in a range between 0.2 nm and 5 nm. These values are merely examples and are not intended to be limiting. The second bonding layer 21 may be formed on the first substrate 10. In one embodiment, the second bonding layer 21 is formed by thermal oxidation or deposition such as CVD, PVD, or ALD. The second etch stop layer 60 may be formed on the second bonding layer 21. In one embodiment, the second etch stop layer 60 is formed by epitaxial growth or by deposition such as CVD. PVD, or ALD. In one embodiment, the second etch stop layer 60 is formed by sputtering or evaporation. The fabrication and related details of the second structure 100B described before may apply here.

As shown in FIG. 11B, a first dielectric layer 81 is formed on the second etch stop layer 60, and a second dielectric layer 82 is formed on the first etch stop layer 30 before the bonding of the first structure 500A and the second structure 1008. In one embodiment, only one of the first dielectric layer 81 and the second dielectric layer 82 is formed before the bonding of the first structure 500A and the second structure 100B. In one embodiment, the first dielectric layer 81 and/or the second dielectric layer 82 is formed by thermal oxidation or deposition such as CVD, PVD, or ALD. In some embodiments, the first dielectric layer 81 and/or the second dielectric layer 82 comprises silicon oxide.

As shown in FIG. 11C, the second structure 100B is flipped and bonded onto the first structure 500A by the first bonding layer 20 to form a bonded structure 500B. The bonding process and related details described before may apply here.

As shown in FIG. 11D, a portion of the second substrate 40 is removed from the bonded structure 500B at approximately the implanted hydrogen layer 70. The removal process and the related details described before may apply here.

The various intermediate stages of forming the semiconductor structure similar to the semiconductor structure shown in FIG. 6 may be substantially similar to the processes described above with respect to FIGS. 11A to 11D. In one embodiment, the second structure 200A shown in FIG. 9A is flipped and bonded onto the first structure 500A shown in FIG. 11A by the first bonding layer 20 to form a bonded structure. Then a portion of the second substrate 40 is removed from the bonded structure at approximately the implanted hydrogen layer 70 to form a semiconductor structure similar to the semiconductor structure shown in FIG. 6. The fabrication processes and the related details described before with respect to FIGS. 11A to 11D may apply here.

The various intermediate stages of forming the semiconductor structure similar to the semiconductor structure shown in FIG. 7 may be substantially similar to the processes described above with respect to FIGS. 11A to 11D. For example, the intermediate layer 51 and the first etch stop layer 31 of the second structure 200A shown in FIG. 9A are replaced with the intermediate layer 52 and the first etch stop layer 32, respectively. Then the second structure is flipped and bonded onto the first structure 500A shown in FIG. 11A by the first bonding layer 20 to form a bonded structure. Then a portion of the second substrate 40 is removed from approximately the implanted hydrogen layer 70 to form a semiconductor structure similar to the semiconductor structure shown in FIG. 7. The intermediate layer 52 and the first etch stop layer 32 may respectively comprise similar materials and formation methods as the intermediate layer 52 and the first etch stop layer 32 described above.

In other methods of fabricating a semiconductor structure similar to the semiconductor structure shown in FIG. 2, 3, 5, 6, or 7, either the intermediate layer 51 or 52 or the second bonding layer 21 may be used to bond the second structure onto the first structure. In either embodiment, the layers under the particular layer used for bonding are formed on the first substrate 10 of the first structure. The layers above the particular layer used for bonding are formed on the second substrate 40 of the second structure. The particular layer used for bonding (e.g. the intermediate layer 51 or 52 or the second bonding layer 21) may be partially or wholly formed before bonding on either or both of the first substrate 10 and the second substrate 40. All other processes described before may apply to these fabrication methods.

For example, to fabricate a semiconductor structure similar to the semiconductor shown in FIG. 5, a first structure and a second structure are provided. The first structure comprises a first substrate 10. The second structure comprises a second substrate 40 with an implanted hydrogen layer 70 inside the second substrate 40, a first etch stop layer 30 on the second substrate 40, a first bonding layer 20 on the first etch stop layer 30, and a second etch stop layer 60 on the first bonding layer 20. Dielectric layer(s) similar to the first dielectric layer 81 and the second dielectric layer 82 described above may be formed before bonding on either or both the first structure and the second structure.

The second structure is flipped and bonded onto the first structure by the second bonding layer 21 to form the bonded structure 500B, wherein the dielectric layers on the first structure and the second structure are bonded to form the second bonding layer 21. In one embodiment, the dielectric layers on the first structure and the second structure are bonded to form the second bonding layer 21. In another embodiment, when only one dielectric layer is formed on the first structure or the second structure before bonding, the dielectric layer forms the second bonding layer 21 of the bonded structure 500B. A portion of the second substrate 40 is then removed from the bonded structure at approximately the implanted hydrogen layer 70 to form a semiconductor structure similar to the semiconductor structure shown in FIG. 5.

The above semiconductor structures may be used to fabricate various types of semiconductor devices, such as a transistor, a diode, a capacitor, and/or a resistor. The transistor may include a bipolar transistor (bipolar junction transistor, BJT), a field-effect transistor (FET), and/or an insulated-gate bipolar transistor (IGBT). The FET may include a planar FET, a FinFET, and/or a Gate-all-around FET (GAAFET). Several embodiments of the process of making semiconductor devices are described as follows.

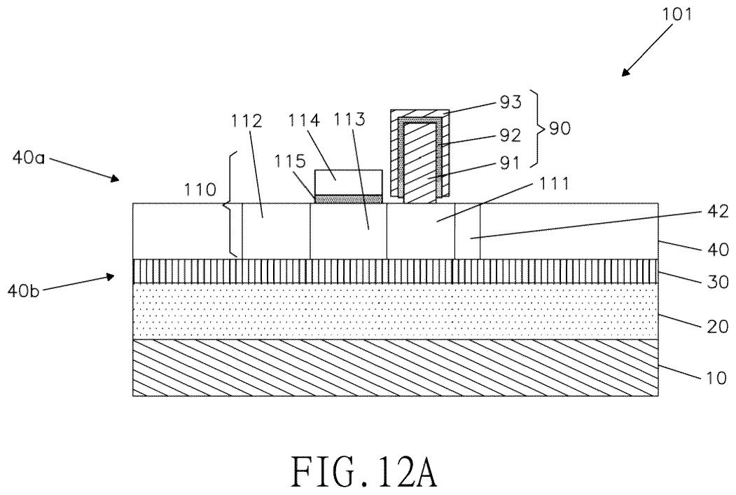

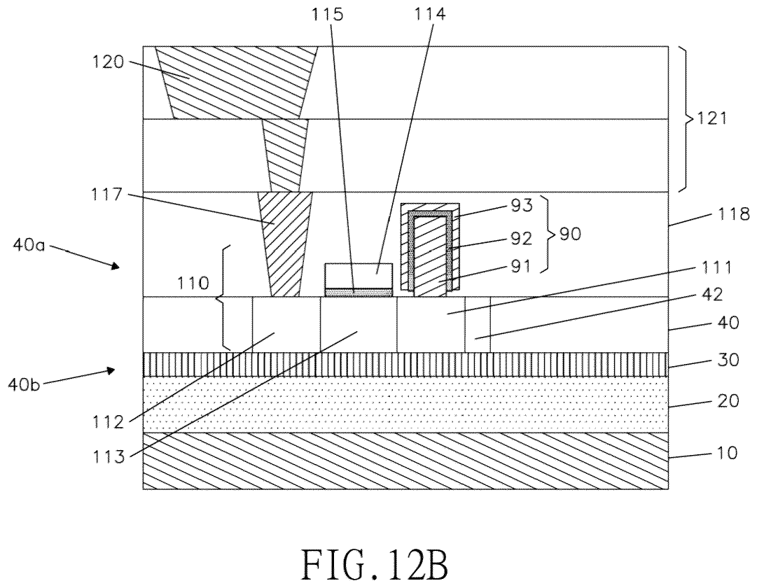

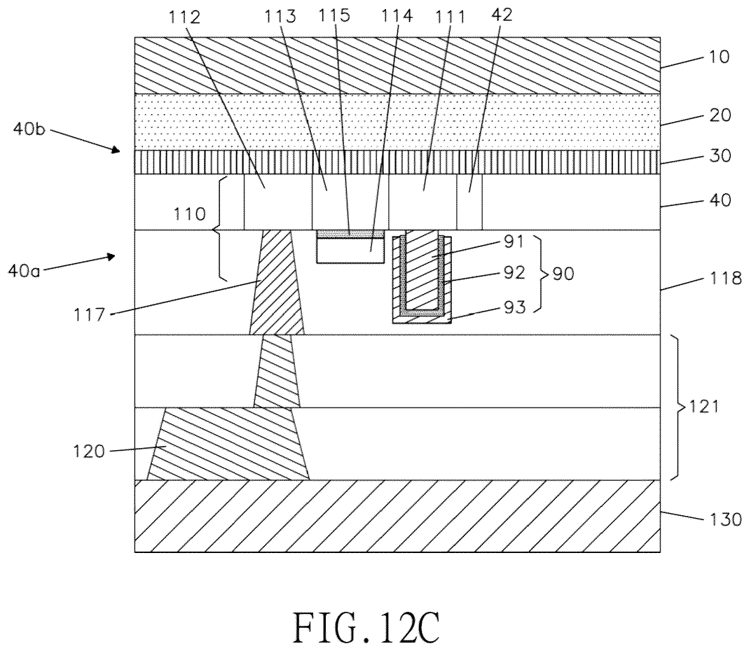

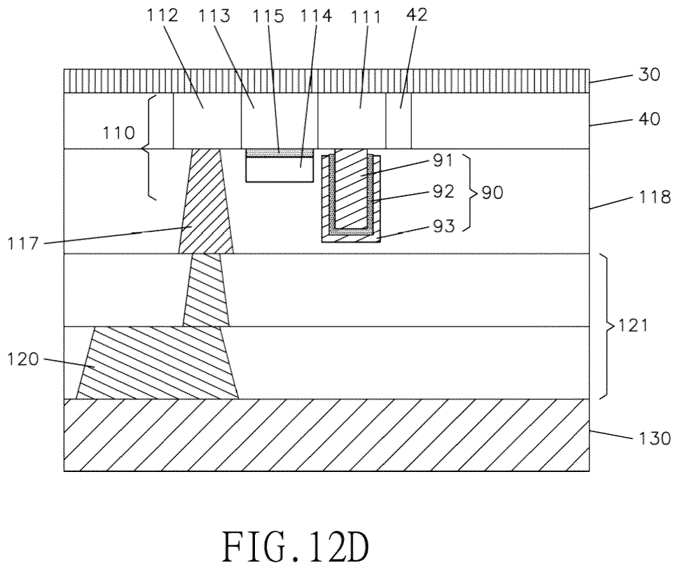

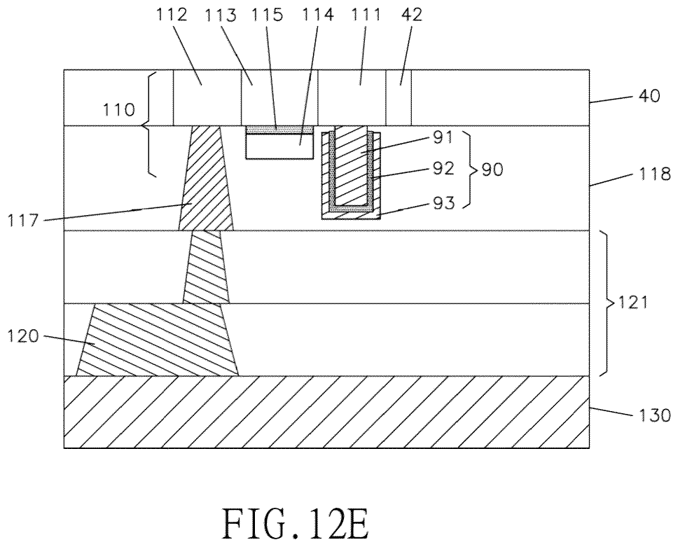

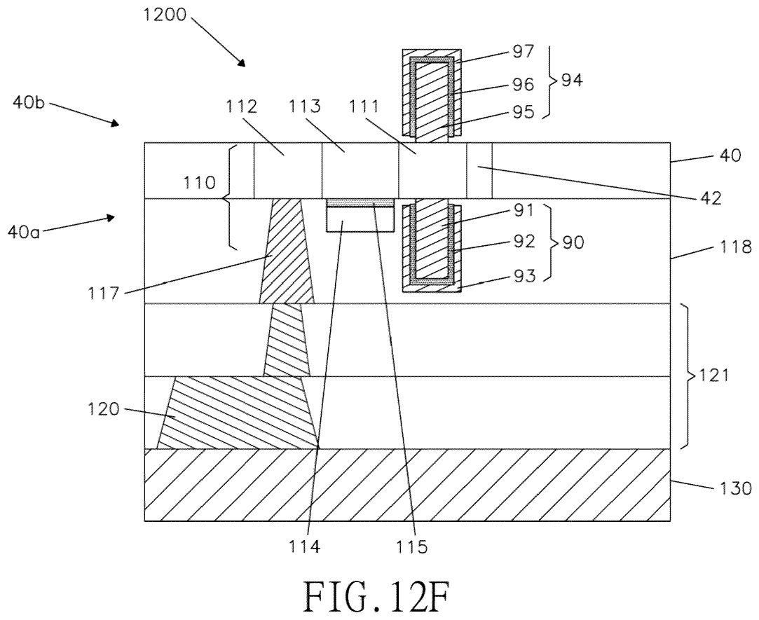

FIGS. 12A to 12F are schematic diagrams illustrating intermediate stages in the manufacture of a semiconductor device according to one embodiment of the present disclosure.

As shown in FIG. 12A, a semiconductor structure 101 is provided (step (a)). The semiconductor structure 101 may be similar to the semiconductor structure 100 described above with regard to FIG. 1. In the embodiment shown in FIG. 12A, the semiconductor structure 101 comprises a first substrate 10, a second substrate 40 on the first substrate 10, a first bonding layer 20 between the first substrate 10 and the second substrate 40, and a first etch stop layer 30 between the first bonding layer 20 and the second substrate 40. In one embodiment, the first etch stop layer 30 has high etch selectivity against the first bonding layer 20. All other descriptions about semiconductor structure 100 may apply here.

As shown in FIG. 12A, a first portion of the semiconductor device is formed (step (b)). In some embodiments, the first portion of the semiconductor device may comprise a device element, such as a transistor, a diode, a capacitor, and/or a resistor. The transistor may be a bipolar transistor (bipolar junction transistor, BJT), a field-effect transistor FET), and/or an insulated-gate bipolar transistor (IGBT). The FET may be a planar FIT, a FinFET, and/or a Gate-all-around FET (GAAFET). In some embodiments, the first portion of the semiconductor device may comprise component(s) of a device element, e.g., a gate structure of a transistor, a dielectric layer of a transistor or a capacitor, or a conductive component of a capacitor. The first portion of the semiconductor device may be formed in the second substrate 40 and/or on a first side 40a of the second substrate 40.

In the embodiment shown in FIG. 12A, the first portion of the semiconductor device includes a transistor 110, e.g., a planar MOSFET. As shown in FIG. 12A, the transistor 110 is formed. The transistor 110 comprises a source region 111, a drain region 112, a channel region 113 between the source region 111 and the drain region 112, a gate structure 114, and a gate dielectric 115. The source region 111, the drain region 112, and the channel region 113 are formed in the second substrate 40. The source region 111 and the drain region 112 may include a first type of dopant (e.g., n-type dopant), and the channel region 113 may include a second type of dopant (e.g., p-type dopant) different from the first type of dopant. As shown in FIG. 12A, the source region 111 and the drain region 112 of the transistor 110 may extend through the thickness of the second substrate 40. The source region 111 and the drain region 112 may be in contact with the first etch stop layer 30. The gate dielectric 115 and the gate structure 114 are formed over the channel region 113.

The transistor 110 may be formed by any suitable method. In one embodiment, the second substrate 40 may be etched to form a trench to define an active area, and an isolation structure 42, e.g., a shallow trench isolation (STI), comprising a dielectric material may be formed in the trench. The gate dielectric 115 and the gate structure 114 are formed on the active area. Specifically, a stack of a gate dielectric layer (not shown) and a gate conductor layer (not shown) is formed on the second substrate 40 and lithographically patterned and etched. The gate dielectric layer may comprise a dielectric material such as silicon oxide, silicon nitride, silicon oxynitride, high k material, including but not limited to hafnium silicate, zirconium silicate, hafnium dioxide, and zirconium dioxide, any suitable materials, or combinations thereof. The gate dielectric layer may be formed by thermal oxidation, deposition such as CVD, PVD, or ALD, sputtering, evaporation, other suitable method, and/or combinations thereof. The gate conductor layer may be formed on the gate dielectric layer. The gate conductor layer may comprise a semiconductor material (e.g., polysilicon), a metallic material (e.g., metal or conductive metal compound), any suitable materials, or combinations thereof. In some embodiments, a stack of semiconductor material layer(s) and metallic material layer(s) may be formed as the gate conductor layer. The gate conductor layer may be formed by epitaxial growth, deposition such as CVD, PVD, or ALD, sputtering, evaporation, other suitable method, and/or combinations thereof. In some embodiments, a subsequent gate replacement process can also be implemented.

In one embodiment, the formation of the transistor 110 comprises doping the second substrate 40. For example, in the embodiment where the source region 111 and the drain region 112 include a first type of dopant (e.g., n-type dopant), and the channel region 113 includes a second type of dopant (e.g., p-type dopant) different from the first type of dopant, a selected type of dopant (e.g., n-type or p-type dopants as described above) may be implanted into the second substrate 40 to form the source region 111, the drain region 112, and/or the channel region 113. In one embodiment, the formation of the transistor 110 comprises etching the second substrate 40. For example, a portion of the second substrate 40 may be etched, and a succeeding epitaxy process may be performed to form the source region 111 and the drain region 112 of the transistor 110.

In the embodiment shown in FIG. 12A, the first portion of the semiconductor device may further include a first capacitor 90. As shown in FIG. 12A, the first capacitor 90 is formed on the first side 40a of the second substrate 40 and may be electrically coupled to the source region 111 of the transistor 110. The first capacitor 90 comprises a first inner conductive component 91, a first outer conductive component 93, and a first capacitor dielectric 92 between the first inner conductive component 91 and the first outer conductive component 93. The first inner conductive component 91 and the first outer conductive component 93 may each comprise at least one conductive material, including but not limited to metal, e.g., W, Ni, Ta, Pt, Cu, Ag, Au, Al, Mo, Ti, Ir, or Ru; doped semiconductor material, e.g., doped-polysilicon, doped-germanium; conductive metal compound such as metal silicide, metal carbide, or metal nitride, e.g., WN. TaN, TaSi, TiN, TiSi, TiSiN, TiAlN, MoN, IrOx, RuOx, or RuTiN. The first capacitor dielectric 92 may comprise silicon oxide, high k material, including but not limited to hafnium silicate, zirconium silicate, hafnium dioxide, and zirconium dioxide, any suitable materials, and/or combinations thereof. The first capacitor 90 may be formed by any suitable method.

In other embodiments, under appropriate etching conditions, for example, hot phosphoric acid may be used as an etchant. In one embodiment, when the first etch stop layer 30 comprises tungsten and the first bonding layer 20 comprises silicon oxide, dry etching can be performed by reactive-ion etching using CHF₃ as an etching gas. In one embodiment, when the first etch stop layer 30 comprises tungsten in first etch stop layer 30 (tungsten and silicon nitride), dry etching can be performed by reactive-ion etching using CHF₃ as an etching gas. In one embodiment, when the first etch stop layer 30 comprises polysilicon and the first bonding layer 20 comprises silicon oxide, dry etching can be performed by remote plasma using NF₃ as an etching gas. In another embodiment, when the first etch stop layer 30 comprises silicon nitride and the first bonding layer 20 comprises silicon oxide, dry etching can be performed using ClF₃/H₂ as gas for reactive-ion etching by decoupled plasma source.

As shown in FIG. 12B, a drain contact 117, a gate contact (not shown), and dielectric layers 118 are formed. The dielectric layers 118 may include one or more stacked dielectric layers. The drain contact 117 is physically and electrically coupled to the drain region 112 and is formed through one or more of the dielectric layers 118. The gate contact is physically and electrically coupled to the gate structure 114 and is formed through one or more of the dielectric layers 118. First interconnect structures 120 and dielectric layers 121 are formed over the dielectric layers 118. The first interconnect structures 120 may include conductive features (e.g., conductive lines and vias) electrically coupled to the first portion of the semiconductor device. In the embodiment shown in FIG. 128, the first interconnect structures 120 may be physically and electrically coupled to the drain contact 117 and/or the gate contact. In some embodiments, one of the conductive lines of the first interconnect structures 120 may be a word line electrically coupled to the gate structure 114. The dielectric layers 121 may include one or more stacked dielectric layers. As shown in FIG. 12B, the first interconnect structures 120 are formed on the first side 40a of the second substrate 40. The dielectric layers 118 and the dielectric layers 121 may include interlayer dielectric (ILD) layers and/or inter-metal dielectric (IMD) layers and may comprise a dielectric material such as silicon oxide, silicon oxynitride, low k materials, a combination thereof, and/or other applicable material and may be formed by deposition such as CVD, PVD, or ALD, spinning, or any suitable method. The drain contact 117 and the gate contact may comprise titanium nitride, tantalum nitride, tungsten, ruthenium, aluminum, copper, some other suitable material(s), or a combination of the foregoing and may be formed in the dielectric layers 118 using a damascene or dual damascene process or any suitable method. The first interconnect structures 120 may comprise titanium nitride, tantalum nitride, tungsten, ruthenium, aluminum, copper, some other suitable material(s), or a combination of the foregoing and may be formed in the dielectric layers 121 using a damascene or dual damascene process or any suitable method.

As shown in FIG. 12C, a third substrate 130 is added on the first side 40a of the second substrate 40, wherein the second substrate 40 is located between the third substrate 130 and the first substrate 10 (step (c)). In some embodiments, the first interconnect structures 120 may be located between the second substrate 40 and the third substrate 130. As shown in FIGS. 12A to 12C, the first portion of the semiconductor device (e.g., the transistor 110) and the first interconnect structures 120 are formed before the addition of the third substrate 130.

In one embodiment, the third substrate 130 is a wafer with a diameter of 6, 8, 12, or 18 inches. The third substrate 130 may be a handle wafer or a device wafer. In one embodiment, the third substrate 130 may comprise glass, polysilicon, or ceramic. In other embodiments, the third substrate 130 may be a single crystalline semiconductor substrate, for example, made of silicon, germanium, silicon germanium, gallium arsenide (GaAs), indium phosphide (InP), silicon carbide (SiC), or gallium nitride (GaN). In one embodiment, the thickness of the third substrate 130 may be in a range between 20 μm and 700 μm. These values are merely examples and am not intended to be limiting. The third substrate 130 may comprise a semiconductor device including but not limited to a transistor, a diode, a capacitor, and/or a resistor. In one embodiment, the interconnect structures or the semiconductor devices of the third substrate 130 (not shown) may be electrically coupled to the first interconnect structures 120. In some embodiments, the third substrate 130 can be formed by epitaxial growth, CVD, PVD, or ALD. In one embodiment, the third substrate 130 may be bonded onto the second substrate 40 by performing suitable process(es) such as adhesive bonding or direct bonding. The third substrate 130 may provide mechanical support to the semiconductor structure to avoid fractures and cracks generated during the manufacture of the semiconductor device.

As shown in FIG. 12D, the first substrate 10 and the first bonding layer 20 are removed to expose the first etch stop layer 30 (step (d)). The first substrate 10 and the first bonding layer 20 can be removed by performing suitable process(es) such as grinding, chemical mechanical polishing (CMP), and etching process. A first etching process may be performed by applying a first etchant to remove the first substrate 10 and/or the first bonding layer 20. In one embodiment, the first substrate 10 is removed by grinding and/or CMP process, and the first bonding layer 20 can be removed by applying a first etchant, e.g., dilute HF (e.g., a weight ratio of H₂O to HF at about 100:1) as previously described. In one embodiment, when using dilute HF as an etchant, the first etch stop layer 30 (e.g., silicon nitride) may have an etch rate of about 1 Å/min, and the first bonding layer 20 (e.g., silicon oxide) may have an etch rate of about 30 Å/min, which renders an etch selectivity of about 30:1 (oxide/nitride). In another embodiment, the first bonding layer 20 (e.g., silicon oxide) can be removed by applying a first etchant, e.g., buffered hydrofluoric acid (a mixture of a buffering agent, such as ammonium fluoride, and hydrofluoric acid). In one embodiment, when using buffered hydrofluoric acid (e.g., a solution of 6.6% HF (weight percentage) and 35.7% NH₄F (weight percentage) in water) as an etchant, the first etch stop layer 30 (e.g., silicon oxynitride) may have an etch rate of about 24.5 nm/min, and the first bonding layer 20 (e.g., silicon oxide) may have an etch rate of about 305.7 nm/min, which renders an etch selectivity of about 12.5:1 (oxide/oxynitride). It should be noted that the etching condition may be adjusted according to actual applications, and the disclosure is not limited thereto. Materials of the first etch stop layer 30 and the first bonding layer 20 may be selected such that the first etch stop layer 30 may function as an etch stop layer with a higher etch selectivity against the first bonding layer 20 and/or may function as an etch stop layer under more desirable etch conditions. Materials of the first etch stop layer 30 may be selected such that the etch stop layer may be easy to remove to expose the second substrate 40 and/or intermediate layer(s) (if there is any) in subsequent steps (described below). In some embodiments, as discussed above, the first etch stop layer 30 may comprise a dielectric material, such that at least a portion of the first etch stop layer 30 may remain on the second substrate 40 to provide electrical insulation between elements of the device(s) (described below).

The first etch stop layer 30 is exposed, after step (d). In the embodiment shown in FIG. 12D, the etch stop layer 30 can protect the transistor 110 and the isolation structure 42 from the etching process. This reduces the difficulty in fabricating semiconductor devices and/or interconnect structures on both sides of the second substrate.

As shown in FIG. 12E, at least a portion of the first etch stop layer 30 is removed (step (e)). The first etch stop layer 30 may be removed by oxide etching, plasma etching, hydrogen peroxide etching, the like, or any suitable method. A second etching process may be performed by applying a second etchant to remove the first etch stop layer 30. In one embodiment, the first etch stop layer 30 comprising silicon nitride can be removed by applying a second etchant. e.g., hot phosphoric acid. However, the disclosure is not limited thereto. At least a portion of the second substrate 40 is exposed after the removal of the first etch stop layer 30. The introduce of the etch stop layer 30 can assure the planarity of the exposed surface of the second substrate 40 and the etch stop layer 30 may be used to monitor the etch endpoint. In the embodiment shown in FIG. 12E, the first etch stop layer 30 is completely removed (or at least the portion of the first etch stop layer 30 overlapped with the transistor 110 and the isolation structure 42 is completely removed). However, in other embodiments, only a portion of the first etch stop layer 30 may be removed by suitable methods such as photolithography and etching process. For example, when the first etch stop layer 30 comprises silicon nitride and the first bonding layer 20 is removed, dry etching can be performed by remote plasma using NF₃ an etching gas to remove only a portion of the first etch stop layer 30, and the first etch stop layer 30 (e.g., silicon nitride) may have an etch selectivity of about 60 to oxide and about 100 to silicon, respectively.

As shown in FIG. 12F, a second portion of the semiconductor device is formed on a second side 40b of the second substrate 40 (step (f)). The second portion of the semiconductor device may comprise a device element, such as a transistor, a diode, a capacitor, and/or a resistor. In some embodiments, the second portion of the semiconductor device may comprise component(s) of a device element, e.g., a gate structure of a transistor, a dielectric layer of a transistor or a capacitor, or a conductive component of a capacitor. In some embodiments, the second portion of the semiconductor device may not be formed directly on the second substrate 40, for example, a dielectric layer (not shown) may be formed on the exposed surface of the second substrate 40, and the second portion of the semiconductor device is formed on the dielectric layer.

In the embodiment shown in FIG. 12F, the second portion of the semiconductor device includes a second capacitor 94. As shown in FIG. 12F, the second capacitor 94 comprising a second inner conductive component 95, a second outer conductive component 97, and a second capacitor dielectric 96 between the second inner conductive component 95 and the second outer conductive component 97 is formed on the second side 40b of the second substrate 40. The second capacitor 94 may be electrically coupled to the source region 111 of the transistor 110. The second capacitor 94 may be formed by any suitable method. Through the formation of a first portion of the semiconductor device (e.g., the transistor 110 and the first capacitor 90) on the first side 40a of the second substrate 40 and/or in the second substrate 40 and the formation of a second portion of the semiconductor device (e.g., the second capacitor 94) on the second side 40b of the second substrate 40, a semiconductor device 1200 may be formed. In the embodiments that only a portion of the first etch stop layer is removed, the second capacitor 94 may be formed on the remained portion of the etch stop layer and may be electrically coupled to the source region 111 of the transistor 110 through a contact structure extending through the first etch stop layer. In the embodiment shown in FIG. 12F, the semiconductor device 1200 may be a memory cell, including but not limited to a DRAM memory cell.

The advantage of the process disclosed herein is that the capacitance of the capacitor in the memory cell can be increased. Firstly, an extra capacitor (e.g., the second capacitor 94) can be formed to increase the equivalent capacitance of the capacitors in a memory cell. Secondly, the capacitance of the extra capacitor (e.g., the second capacitor 94) can be increased since an extra capacitor (e.g., the second capacitor 94) with larger size can be fabricated on the second side 40b of the second substrate 40 due to increase of available area. Moreover, the process disclosed herein can help to reduce the die size and therefore increase the unit density.

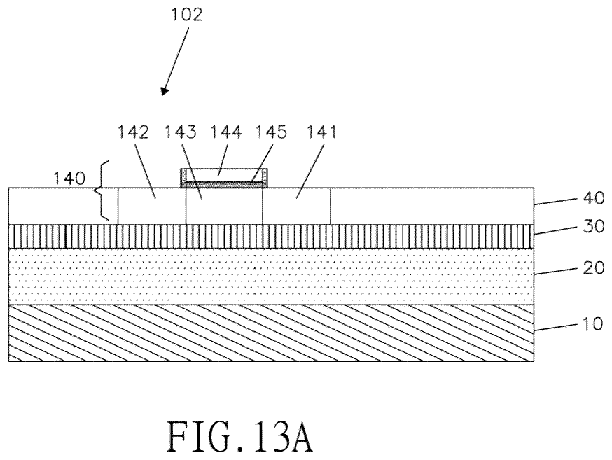

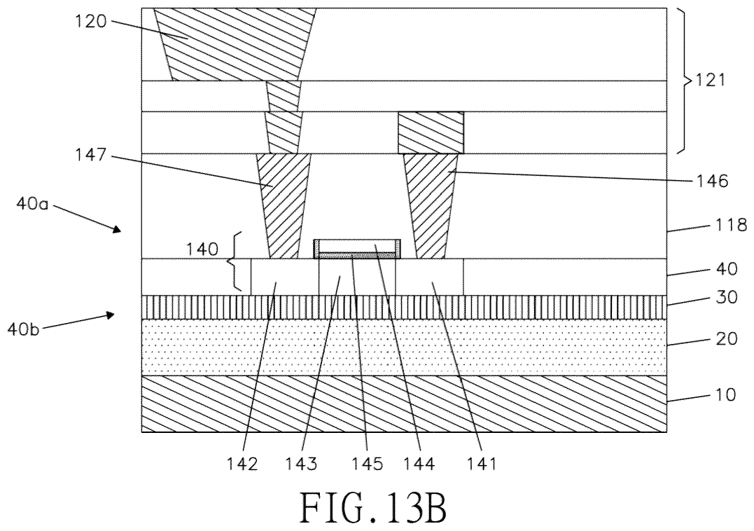

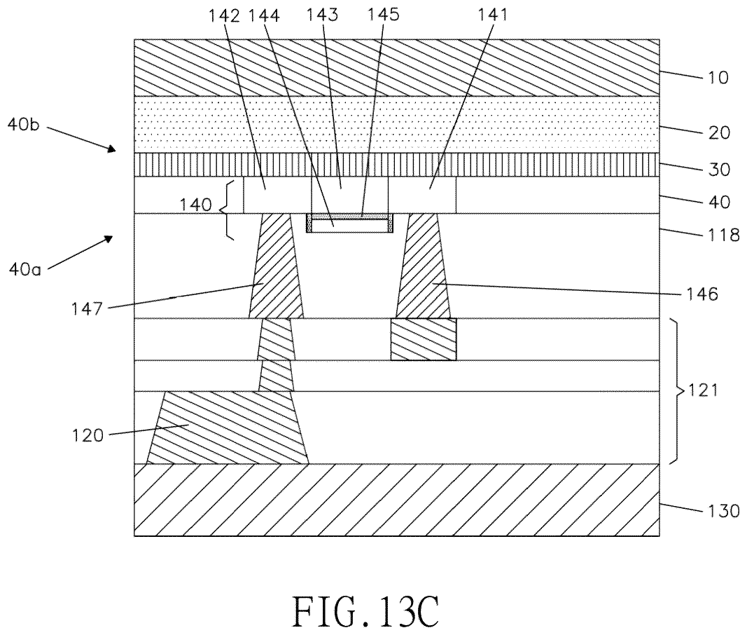

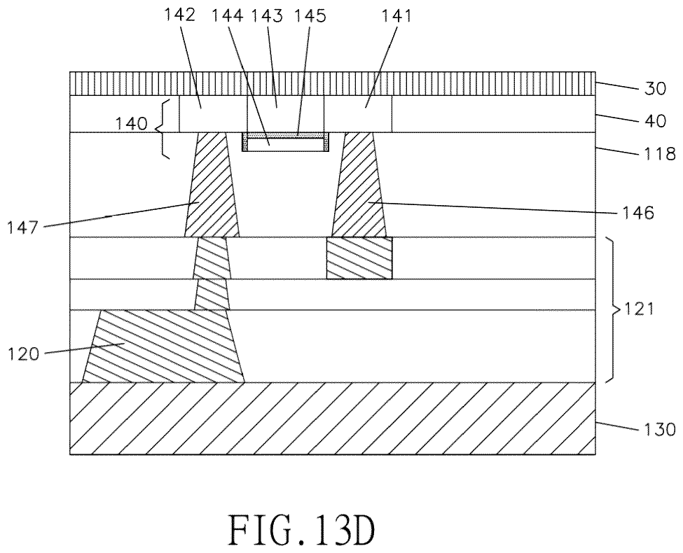

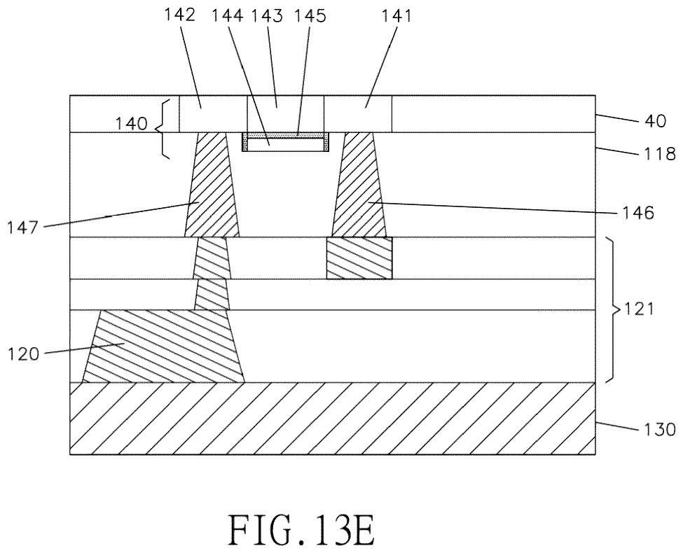

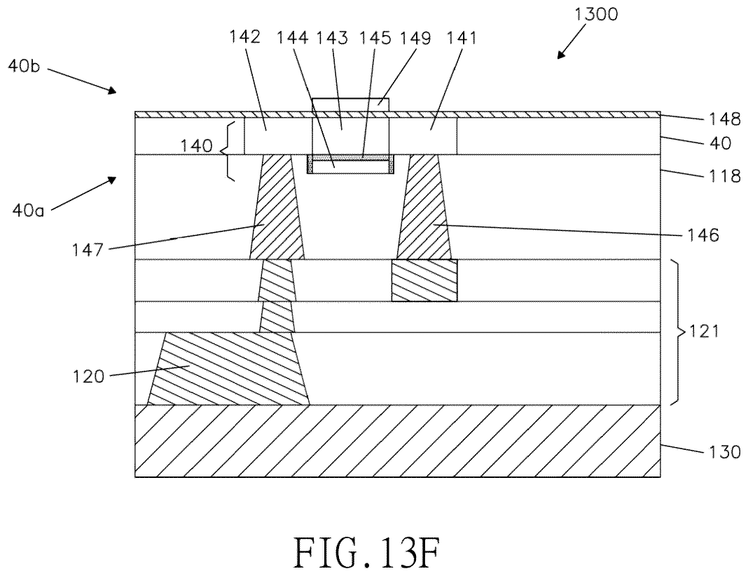

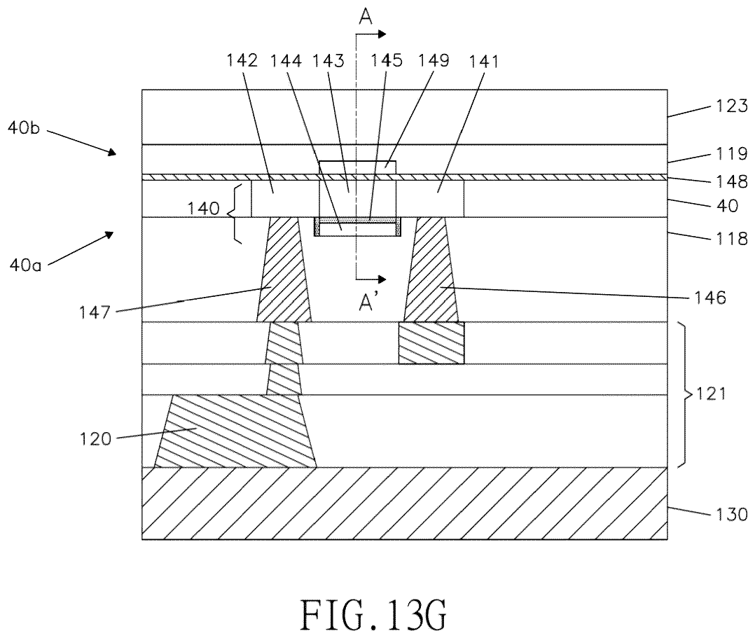

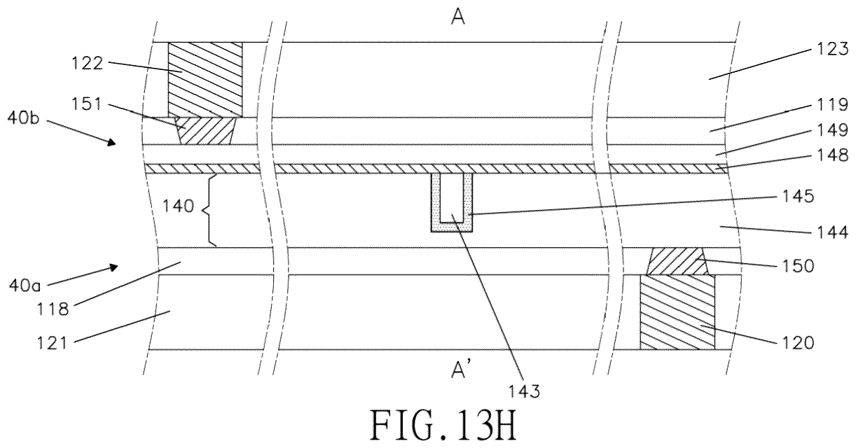

FIGS. 13A to 13H are schematic diagrams illustrating intermediate stages in the manufacture of a semiconductor device according to one embodiment of the present disclosure.

As shown in FIG. 13A, a semiconductor structure 102 is provided (step (a)). The semiconductor structure 102 may be similar to the semiconductor structure 100 described above with regard to FIG. 1. In the embodiment shown in FIG. 13A, the semiconductor structure 102 comprises a first substrate 10, a second substrate 40 on the first substrate 10, a first bonding layer 20 between the first substrate 10 and the second substrate 40, and a first etch stop layer 30 between the first bonding layer 20 and the second substrate 40. In one embodiment, the first etch stop layer 30 has high etch selectivity against the first bonding layer 20. All other descriptions about semiconductor structure 100 may apply here.

As shown in FIG. 13A, a first portion of the semiconductor device is formed (step (b)). In the embodiment shown in FIG. 13A, the first portion of the semiconductor device includes a FinFET 140. The FinFET 140 comprising a first source/drain region 141, a second source/drain region 142, a channel region 143 between the first source/drain region 141 and the second source/drain region 142, a first gate structure 144, and a first gate dielectric 145 is formed. The first source/drain region 141, the second source/drain region 142, and the channel region 143 are formed in the second substrate 40. Specifically, the first source/drain region 141, the second source/drain region 142, and the channel region 143 may be formed in a fin structure of the second substrate 40. In the embodiment shown in FIG. 13A, the first source/drain region 141 and the second source/drain region 142 of the FinFET 140 may extend through the second substrate 40 and are in contact with the first etch stop layer 30. The channel region 143 is wrapped around by the first gate structure 144 and the first gate dielectric 145, such that the first source/drain region 141, the second source/drain region 142, the channel region 143, and the first gate structure 144 may function altogether as a fin field-effect transistor (FinFET). The first gate structure 144 may have a lengthwise direction substantially perpendicular to the lengthwise direction of the fin structure.

The FinFET 140 may be formed by any suitable method. The second substrate 40 may be etched to define the fin structure. The first gate dielectric 145 and the first gate structure 144 are formed on the fin structure. The first gate dielectric 145 may comprise silicon oxide, silicon nitride, high k material, including but not limited to hafnium silicate, zirconium silicate, hafnium dioxide, and zirconium dioxide, combinations thereof, or multi-layers thereof. The first gate structure 144 may comprise a semiconductor material (e.g., polysilicon), a metallic material (e.g., metal or conductive metal compound), combinations thereof, or multi-layers thereof. In some embodiments, first gate dielectric material layer(s) and first gate structure material layer(s) may be deposited or thermally grown and then lithographically patterned and etched according to acceptable techniques to form the first gate dielectric 145 and the first gate structure 144. In some embodiments, a subsequent gate replacement process can also be implemented. In one embodiment, the formation of the FinFET 140 comprises etching the second substrate 40. For example, in one embodiment, the first source/drain region 141 and the second source/drain region 142 may be formed by etching the fin structure of the second substrate 40 and epitaxial growth of suitable material. In one embodiment, the formation of the FinFET 140 comprises doping the second substrate 40. For example, in the embodiment where the first source/drain region 141 and the second source/drain region 142 include a first type of dopant (e.g., n-type dopant), and the channel region 143 includes a second type of dopant (e.g., p-type dopant) different from the first type of dopant, a selected type of dopant (e.g., n-type or p-type dopants a % described above) may be implanted into the second substrate 40 to form the first source/drain region 141, the second source/drain region 142, and/or the channel region 143.

As shown in FIG. 13B, a first source/drain contact 146, a second source/drain contact 147, a first gate contact 150 (shown in FIG. 13H), and dielectric layers 118 may be formed. The dielectric layers 118 may include one or more stacked dielectric layers. The first source/drain contact 146 and the second source/drain contact 147 are physically and electrically coupled to the first source/drain region 141 and the second source/drain region 142 respectively and are formed through one or more of the dielectric layers 118. The first gate contact 150 is physically and electrically coupled to the first gate structure 144 and is formed through one or more of the dielectric layers 118. First interconnect structures 120 and dielectric layers 121 are formed over the dielectric layers 118 on the first side 40a of the second substrate 40. The first interconnect structures 120 may include conductive features (e.g., conductive lines and vias) electrically coupled to the first portion of the semiconductor device. In the embodiment shown in FIGS. 13B and 13H, the first interconnect structures 120 may be physically and electrically coupled to the first source/drain contact 146, the second source/drain contact 147, and/or the first gate contact 150. In one embodiment, the first interconnect structures 120 may also be electrically coupled to a second portion of the semiconductor device formed on the second side 40b of the second substrate 40. The conductive lines of the first interconnect structures 120 may extend in different directions. The dielectric layers 121 may include one or more stacked dielectric layers. The dielectric layers 118 and the dielectric layers 121 may include interlayer dielectric (ILD) layers and/or inter-metal dielectric (IMD) layers. The materials and processes for forming the dielectric layers 118 and 121 may be similar to that of described with respect to FIG. 12B. The first source/drain contact 146, the second source/drain contact 147, and the first gate contact 150 may comprise similar materials as discussed above for the drain contact 117 and may be formed in the dielectric layers 118 using a damascene or dual damascene process or any suitable method. The first interconnect structures 120 may comprise similar materials as discussed above with respect to FIG. 12B for the first interconnect structures 120 and may be formed in the dielectric layers 121 using a damascene or dual damascene process or any suitable method.

As shown in FIG. 13C, a third substrate 130 is added on the first side 40a of the second substrate 40, wherein the second substrate 40 is located between the third substrate 130 and the first substrate 10 (step (c)). As shown in FIGS. 13A to 13C, the first portion of the semiconductor device (e.g., the FinFET 140) and the first interconnect structures 120 are formed before the addition of the third substrate 130. The addition of the third substrate 130 may be substantially similar to the processes described above with respect to FIG. 12C, and the related description is omitted for brevity.

As shown in FIG. 13D, the first substrate 10 and the first bonding layer 20 are removed to expose the first etch stop layer 30 (step (d)). The removal of the first substrate 10 and the first bonding layer 20 may be substantially similar to the processes described above with respect to FIG. 12D, and the related description is omitted for brevity.

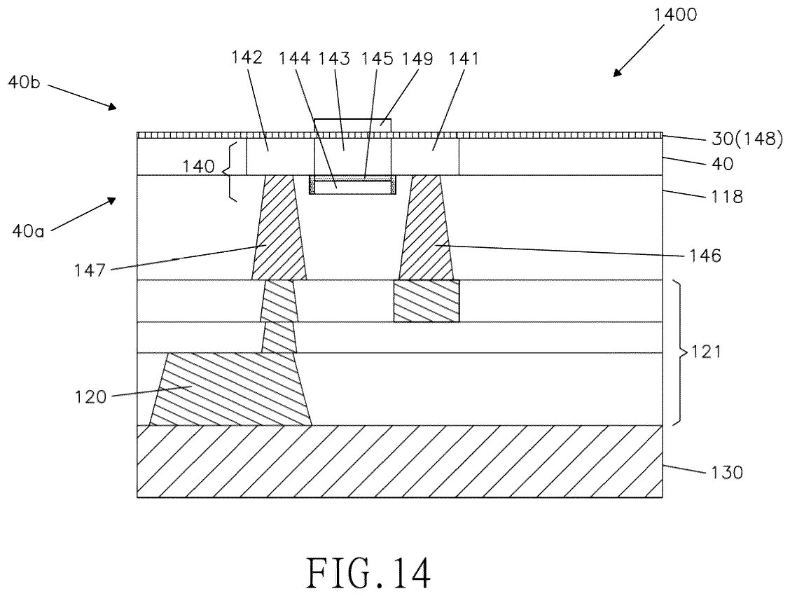

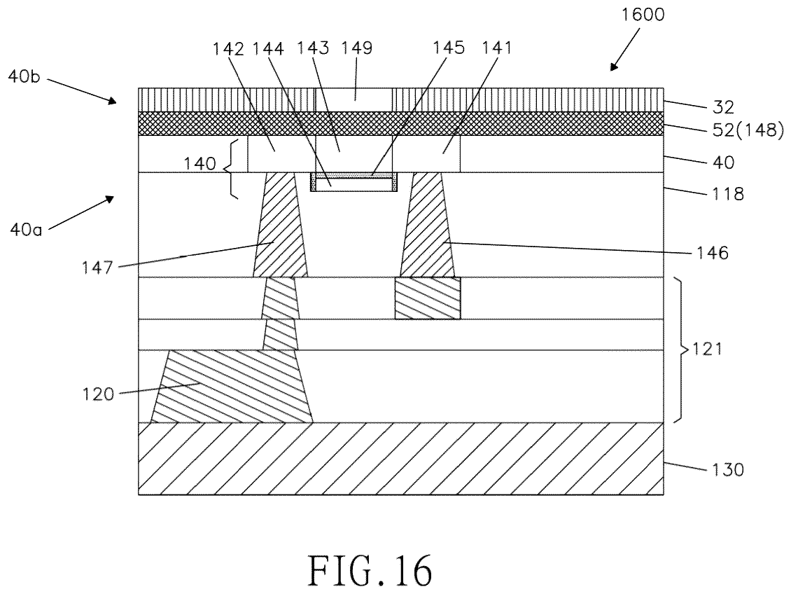

As shown in FIG. 13E, at least a portion of the first etch stop layer 30 is removed (step (e)). The removal of the first etch stop layer 30 may be substantially similar to the processes described above with respect to FIG. 12E, and the related description is omitted for brevity, in the embodiment shown in FIG. 13E, the first etch stop layer 30 is completely removed for at least the portion of the first etch stop layer 30 overlapped with the FinFET 140 is completely removed). However, in other embodiments (e.g., the embodiments shown in FIGS. 14 and 16), only a portion of the first etch stop layer 30 may be removed.

As shown in FIG. 13F, a second portion of the semiconductor device is formed on the second side 40b of the second substrate 40 (step (f)). In the embodiment shown in FIG. 13F, the second portion of the semiconductor device may include a second gate dielectric 148 and/or a second gate structure 149. The second gate structure 149 is overlapped with the channel region 143 of the FinFET 140. In the embodiment shown in FIG. 13F, the second gate structure 149 has a lengthwise direction substantially perpendicular to the lengthwise direction of the fin structure. However, the lengthwise direction of the second gate structure 149 may be adjusted according to actual application. The second gate dielectric 148 may comprise similar materials as discussed above for the first gate dielectric 145, and the second gate structure 149 may comprise similar materials as discussed above for the first gate structure 144. In some embodiments, a stack of a second gate dielectric layer and a second gate conductor layer (not shown) may be deposited or thermally grown on the second side 40b of the second substrate 40. The stack of material layers may then be lithographically patterned and etched according to acceptable techniques to form the second gate dielectric 148 and the second gate structure 149. Through the formation of a first portion of the semiconductor device (e.g., the FinFET 140) on the first side 40a of the second substrate 40 and/or in the second substrate 40 and the formation of a second portion of the semiconductor device (e.g., the second gate dielectric 148 and the second gate structure 149) on the second side 40b of the second substrate 40, a semiconductor device 1300 may be formed.

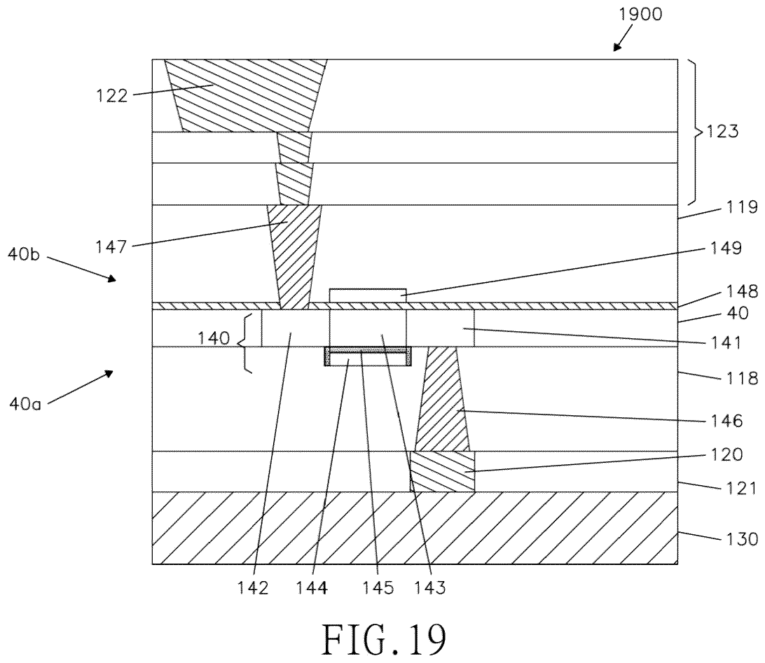

FIG. 13H is a cross-sectional schematic view of the semiconductor structure in FIG. 130 along the line A-A′. As shown in FIGS. 13G and 13H, a second gate contact 151 and dielectric layers 119 may be formed. The dielectric layers 19 may include one or more stacked dielectric layers. The second gate contact 151 is physically and electrically coupled to the second gate structure 149 and is formed through one or more of the dielectric layers 119. Second interconnect structures 122 and dielectric layers 123 are formed over the dielectric layers 119 on the second side 40b of the second substrate 40. The second interconnect structures 122 may include conductive features (e.g., conductive lines and vias) electrically coupled to the second portion of the semiconductor device. In the embodiment shown in FIG. 13H, the second interconnect structures 122 are physically and electrically coupled to the second gate contact 151. In one embodiment, the second interconnect structures 122 may also be electrically coupled to the first portion of the semiconductor device (e.g., the FinFET 140, as described below in greater detail with respect to FIG. 19. The dielectric layers 123 may include one or more stacked dielectric layers. The dielectric layers 119 and the dielectric layers 123 may include interlayer dielectric (ILD) layers and/or inter-metal dielectric (IMD) layers. The materials and processes for forming the dielectric layers 119 and 123 may be similar to that of the dielectric layers 118 and 121 described with respect to FIG. 128. The second gate contact 151 may comprise similar materials as discussed above for the drain contact 117 and may be formed in the dielectric layers 119 using a damascene or dual damascene process or any suitable method. The second interconnect structures 122 may comprise similar materials as discussed above with respect to FIG. 12B for the first interconnect structures 120 and may be formed in the dielectric layers 123 using a damascene or dual damascene process or any suitable method. As such, the second interconnect structures 122 may be formed on a second side 40b of the second substrate 40 after the removal of the first substrate 10 and the first bonding layer 20 and after the removal of the first etch stop layer 30. The process described herein may be used to fabricate interconnect structures on both sides of the second substrate, which may provide additional options for routing and may reduce the size of the circuit and/or improve the performance of the semiconductor devices. In the embodiment shown in FIGS. 13G and 13H, the first gate structure 144 and the second gate structure 149 may extend across a plurality of fin structures, and the gate contacts 150 and 151 may not overlap with the channel region 143 of the FinFET 140.

FIG. 14 is a schematic diagram illustrating an intermediate stage in the manufacture of a semiconductor device according to one embodiment of the present disclosure.

As shown in FIG. 14, a semiconductor device 1400 is provided. The semiconductor device 1400 may be similar to the semiconductor device 1300 described above with regard to FIG. 13F where like reference numerals indicate like elements. The process for manufacturing semiconductor device 1400 may be substantially similar to the process described above with respect to FIGS. 13A to 13H. In the embodiment shown in FIG. 14, the first etch stop layer 30 of the semiconductor structure 102 provided in step (a) may comprise a dielectric material, such as silicon nitride, silicon oxynitride, high k material, including but not limited to hafnium silicate, zirconium silicate, hafnium dioxide, and zirconium dioxide, or combinations thereof. As shown in FIG. 14, instead of completely removing the first etch stop layer 30 (as shown in the embodiment in FIG. 13E), at least a layer of the first etch stop layer 30 may remain on the second side 40b of the second substrate 40 and the layer of the first etch stop layer 30 may become the second gate dielectric 148 of the semiconductor device 1400. In one embodiment, at least a portion of the first etch stop layer 30 may be removed (step (e)) to reduce the thickness of the first etch stop layer 30 in order to provide a second gate dielectric 148 with a desired thickness. Second gate contact (not shown) and second interconnect structures (not shown) similar to the second gate contact 151 and the second interconnect structures 122 described above with regard to FIGS. 13G and 13H may also be formed. The process disclosed herein may provide a gate dielectric having good contact with the second substrate and may reduce the difficulty of forming a high-quality gate dielectric on the substrate, especially on the second side of the substrate.

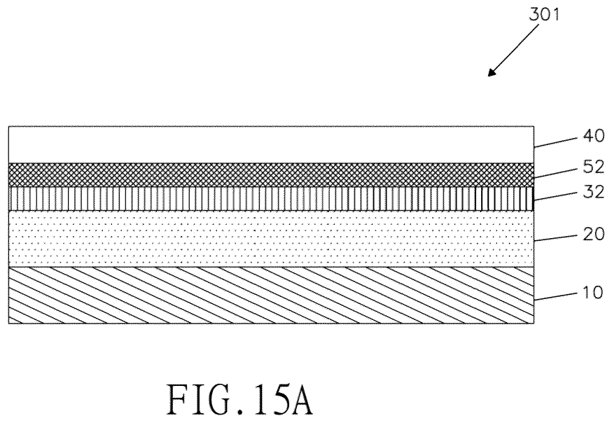

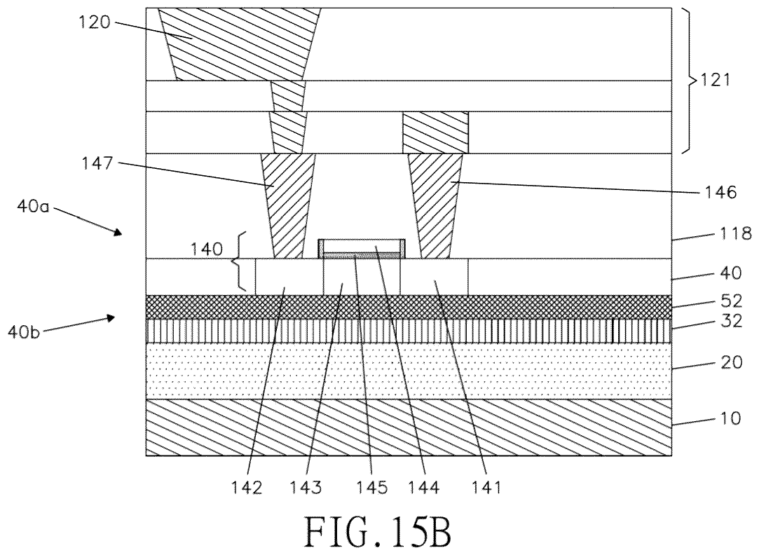

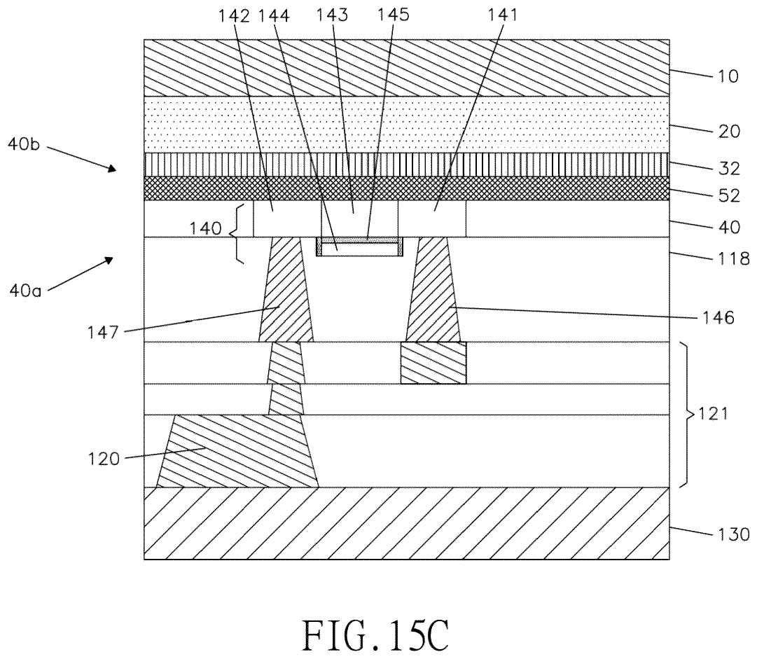

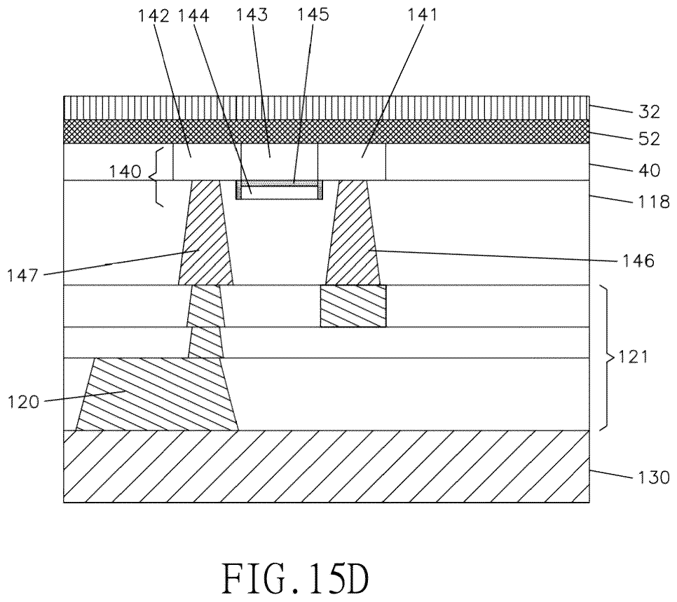

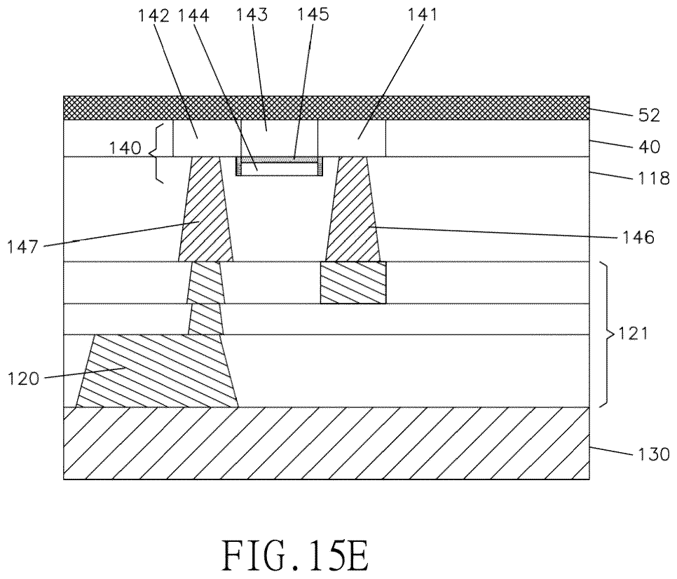

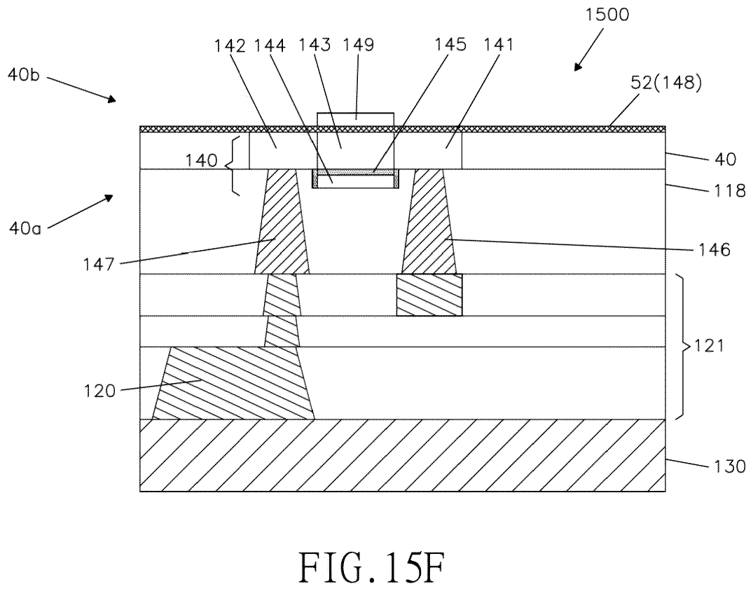

FIGS. 15A to 15F are schematic diagrams illustrating intermediate stages in the manufacture of a semiconductor device according to one embodiment of the present disclosure.

As shown in FIG. 15A, a semiconductor structure 301 is provided (step (a)). The semiconductor structure 301 may be similar to the semiconductor structure 300 described above with regard to FIG. 3. In the embodiment shown in FIG. 15A, the semiconductor structure 301 comprises a first substrate 10, a second substrate 40 on the first substrate 10, a first bonding layer 20 between the first substrate 10 and the second substrate 40, a first etch stop layer 32 between the first bonding layer 20 and the second substrate 40, and an intermediate layer 52 between the first etch stop layer 32 and the second substrate 40. In one embodiment, the first etch stop layer 32 has high etch selectivity against the first bonding layer 20. The intermediate layer 52 may comprise silicon oxide, high k material, including but not limited to hafnium silicate, zirconium silicate, hafnium dioxide, and zirconium dioxide, or combinations thereof. All other descriptions about semiconductor structure 300 may apply here.

As shown in FIG. 150, a first portion of the semiconductor device is formed (step (b)). In the embodiment shown in FIG. 15B, the first portion of the semiconductor device includes a FinFET 140. The FinFET 140 may be similar to the FinFET 140 as shown in FIG. 13A where like reference numerals indicate like elements and may be formed using a method similar to that described above with respect to FIG. 13A. In the embodiment shown in FIG. 15B, a first source/drain contact 146, a second source/drain contact 147, dielectric layers 118, first interconnect structures 120, and dielectric layers 121 similar to that of described above with respect to FIG. 13B may also be formed.

As shown in FIG. 15C, a third substrate 130 is added on the first side 40a of the second substrate 40, wherein the second substrate 40 is located between the third substrate 130 and the first substrate 10 (step (c)). The addition of the third substrate 130 may be substantially similar to the processes described above with respect to FIGS. 12C and 13C, and the related description is omitted for brevity.

As shown in FIG. 15D, the first substrate 10 and the first bonding layer 20 are removed to expose the first etch stop layer 32 (step (d)). The removal of the first substrate 10 and the first bonding layer 20 may be substantially similar to the processes described above with respect to FIGS. 12D and 13D, and the related description is omitted for brevity.

As shown in FIG. 15E, at least a portion of the first etch stop layer 32 is removed to expose the intermediate layer 52 (step (e)). The first etch stop layer 32 may be removed by oxide etching, plasma etching, hydrogen peroxide etching, the like, or any suitable method. A second etching process may be performed by applying a second etchant to remove the first etch stop layer 32. In one embodiment, the first etch stop layer 32 comprising silicon nitride can be removed by applying a second etchant, e.g., hot phosphoric acid as previously described. However, the disclosure is not limited thereto. At least a portion of the intermediate layer 52 is exposed after the removal of the first etch stop layer 32. In the embodiment shown in FIG. 15E, the first etch stop layer 32 is completely removed (or at least the portion of the first etch stop layer 32 overlapped with the FinFET 140 is completely removed). However, in other embodiments (e.g., the embodiment shown in FIG. 16), only a portion of the first etch stop layer 32 may be removed by suitable methods such as photolithography and etching process.

As shown in FIG. 15F, a second portion of the semiconductor device is formed on the second side 40b of the second substrate 40 (step (f). In the embodiment shown in FIG. 15F, the second portion of the semiconductor device includes a second gate structure 149. The second gate structure 149 may be similar to and may be formed by similar methods as described for the second gate structure 149 with respect to FIG. 13F. As shown in FIG. 15F, the second gate structure 149 is formed on an exposed surface of the intermediate layer 52 on the second side 40b of the second substrate 40. As such, the intermediate layer 52 of the semiconductor structure 301, which may comprise silicon oxide or high k material, may become the second gate dielectric 148 of the semiconductor device 1500. In some embodiments, at least a portion of the intermediate layer 52 may be removed to reduce the thickness of the intermediate layer 52 in order to provide a second gate dielectric 148 with a desired thickness. In some other embodiments, the intermediate layer 52 of the semiconductor structure (e.g., the semiconductor structure 301) can be formed with a desired thickness and further removal of the intermediate layer 52 can be omitted. Second gate contact (not shown) and second interconnect structures (not shown) similar to the second gate contact 151 and the second interconnect structures 122 described above with regard to FIGS. 13G and 13H may also be formed. The process disclosed herein may provide a gate dielectric made by desired material and having good contact with the second substrate and may reduce the difficulty of forming a high-quality gate dielectric on the substrate, especially on the second side of the substrate.

FIG. 16 is a schematic diagram illustrating an intermediate stage in the manufacture of a semiconductor device according to one embodiment of the present disclosure.

As shown in FIG. 16, a semiconductor device 1600 is provided. The semiconductor device 1600 may be similar to the semiconductor device 1500 described above with regard to FIG. 15F where like reference numerals indicate like elements. For example, the intermediate layer 52 of the semiconductor structure (e.g., semiconductor structure 301) may become the second gate dielectric 148 of the semiconductor device 1600. In the embodiment shown in FIG. 16, instead of completely removing the first etch stop layer 32 (as shown in the embodiment in FIG. 15E), only a portion of the first etch stop layer 32 is removed. Specifically, the first etch stop layer 32 may be partially removed by suitable methods such as photolithography and etching process to form trenches and/or openings exposing at least a portion of the intermediate layer 52. A second gate structure 149 may be formed by filling the trenches and/or openings with semiconductor material (e.g., polysilicon) and/or metallic material (e.g., metal or conductive metal compound), and the filling material outside of the trenches and/or openings may be removed by suitable methods such as grinding, chemical mechanical polishing (CMP), and etching process. The filling material may be formed by epitaxial growth, deposition such as CVD, PVD, or ALD, sputtering, evaporation, other suitable method, and/or combinations thereof. Second gate contact (not shown) and second interconnect structures (not shown) similar to the second gate contact 151 and the second interconnect structures 122 described above with regard to FIGS. 13G and 13H may also be formed.

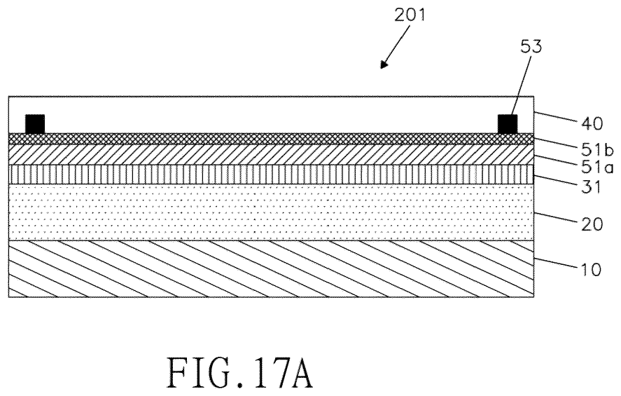

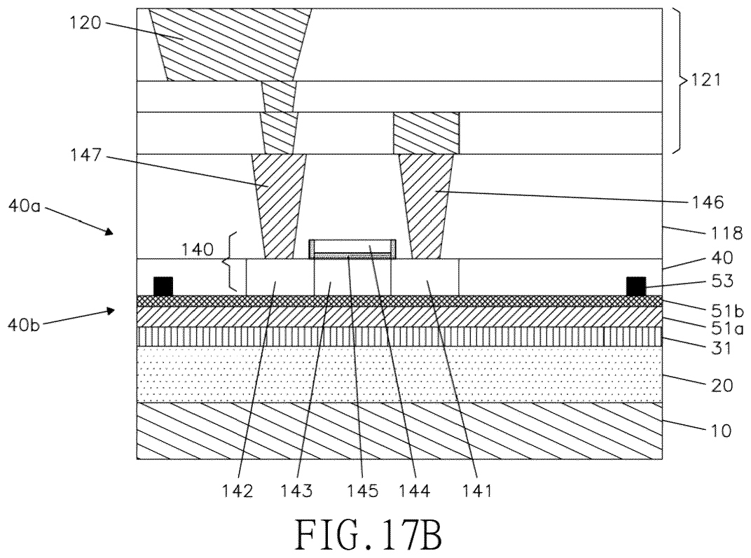

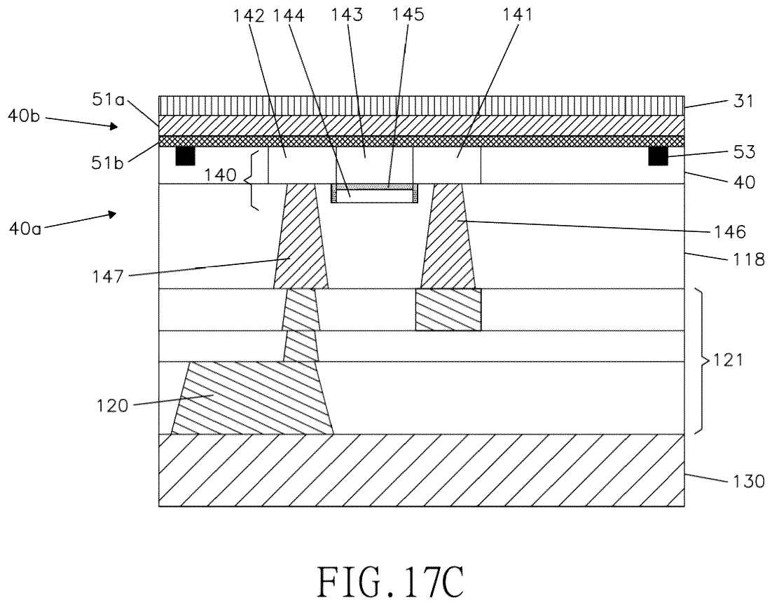

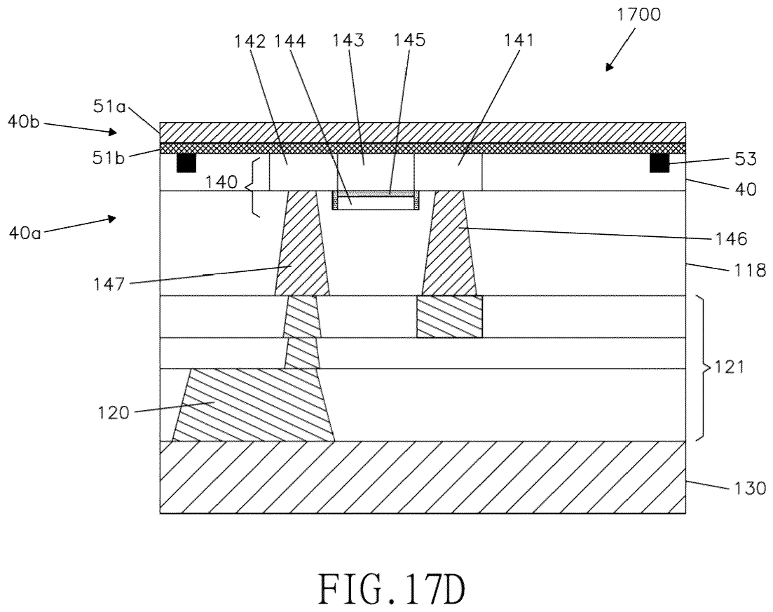

FIGS. 17A to 17D are schematic diagrams illustrating intermediate stages in the manufacture of a semiconductor device according to one embodiment of the present disclosure.

As shown in FIG. 17A, a semiconductor structure 201 is provided (step (a)). The semiconductor structure 201 may be similar to the semiconductor structure 200 described above with regard to FIG. 2 where like reference numerals indicate like elements. In the embodiment shown in FIG. 17A, the semiconductor structure 201 comprises a first substrate 10, a second substrate 40 on the first substrate 10, a first bonding layer 20 between the first substrate 10 and the second substrate 40, a first etch stop layer 31 between the first bonding layer 20 and the second substrate 40, and an intermediate layer 51 between the first etch stop layer 31 and the second substrate 40. In one embodiment, the first etch stop layer 31 has high etch selectivity against the first bonding layer 20.

In the embodiment shown in FIG. 17A, the intermediate layer 51 includes a multi-layer structure including a first intermediate layer 51a and a second intermediate layer 51b between the first etch stop layer 31 and the second substrate 40. The first intermediate layer 51a may comprise a conductive material such as doped semiconductor material, metal, conductive metal compound, or combinations thereof. In some embodiments, the first intermediate layer 51a may be patterned. In some embodiments, the patterning process of the first intermediate layer 51a may be performed according to the alignment mark 53 disposed in the second substrate 40. The formation of the first intermediate layer 51a may be similar to that of the intermediate layer 51 described above with respect to FIGS. 2 and 9A, and additional description is omitted herein for brevity. The second intermediate layer 51b may comprise silicon oxide, high k material, or combinations thereof, and may be formed before the formation of the first intermediate layer 51a by deposition or any suitable method. All other descriptions about semiconductor structure 200 may apply here.

As shown in FIG. 17B, a first portion of the semiconductor device (FinFET 140) is formed (step (b)). The FinFET 140 may be similar to the FinFET 140 as shown in FIG. 13A where like reference numerals indicate like elements and may be formed using a method similar to that described above with respect to FIG. 13A. A first source/drain contact 146, a second source/drain contact 147, dielectric layers 118, first interconnect structures 120, and dielectric layers 121 similar to that of described above with respect to FIG. 13B may also be formed. The fabrication of the FinFET 140, the contacts 146 and 147, and/or the first interconnect structures 120 may be performed according to the alignment mark 53.

As shown in FIG. 17C, a third substrate 130 is added on the first side 40a of the second substrate 40 (step (c)), and then the first substrate 10 and the first bonding layer 20 are removed to expose the first etch stop layer 31 (step (d)). All other descriptions about the process described with respect to FIGS. 12A to 12D, FIGS. 13C-13D and 15C-15D may apply here if applicable.

As shown in FIG. 17D, at least a portion of the first etch stop layer 31 is removed (step (e)). After the removal of the first etch stop layer 31, at least a portion of the first intermediate layer 51a may be exposed. In the embodiment shown in FIG. 17D, the first etch stop layer 31 is completely removed (or at least the portion of the first etch stop layer 31 overlapped with the FinFET 140 is completely removed). However, in other embodiments, only a portion of the first etch stop layer 31 may be removed by suitable methods such as photolithography and etching process. Second gate contact (not shown) and second interconnect structures (not shown) similar to the second gate contact 151 and the second interconnect structures 122 described above with regard to FIGS. 13G and 13H may also be formed. As such, a semiconductor device 1700 similar to the semiconductor device 1300, 1400, 1500, and/or 1600 described above is provided, where like reference numerals indicate like elements. In the embodiment shown in FIG. 17D, the first intermediate layer 51a may become the second gate structure 149 of the semiconductor device 1700, and the second intermediate layer 51b may become the second gate dielectric 148 of the semiconductor device 1700. The process disclosed herein may provide gate structure and/or gate dielectric with better quality and having good contact with the second substrate, which may reduce the difficulty of forming gate structure and/or gate dielectric on the second side of the substrate.

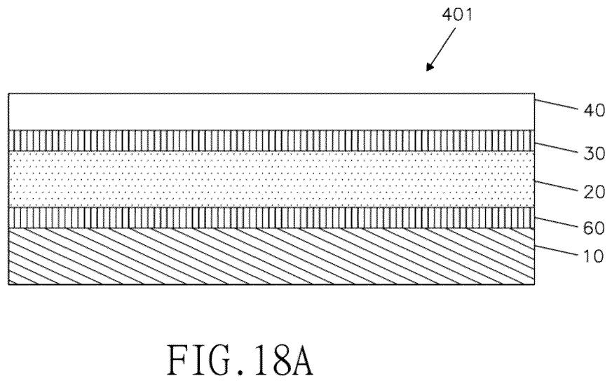

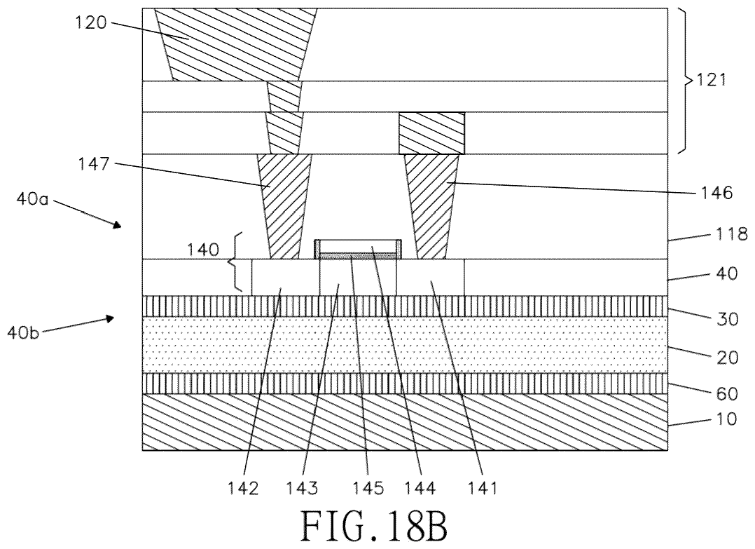

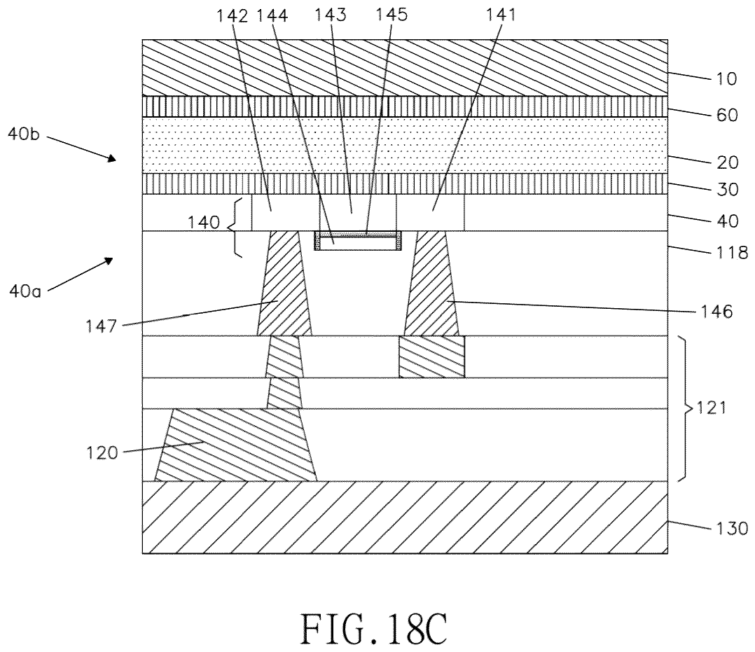

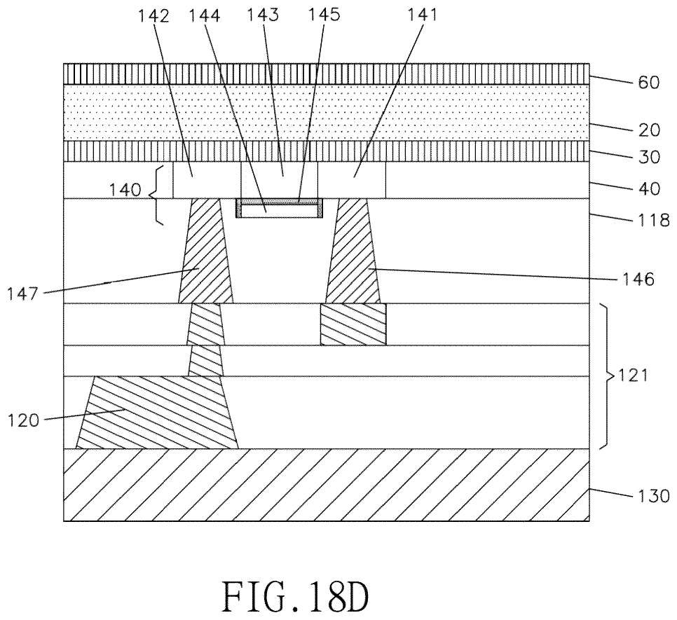

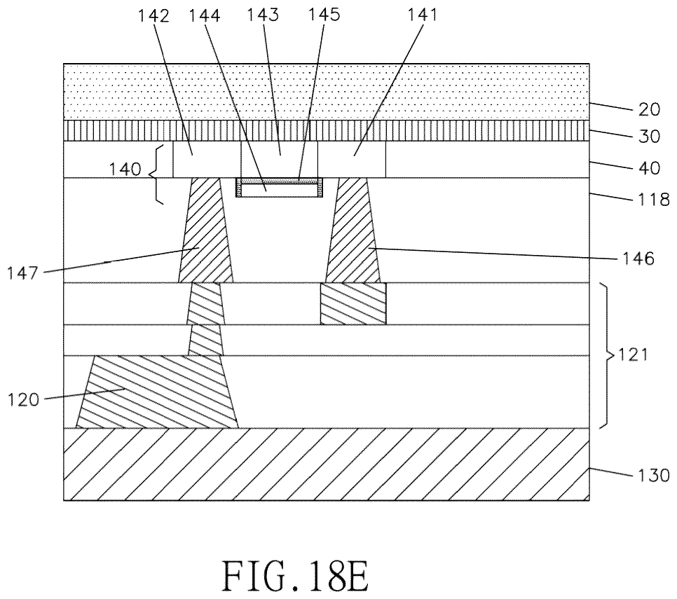

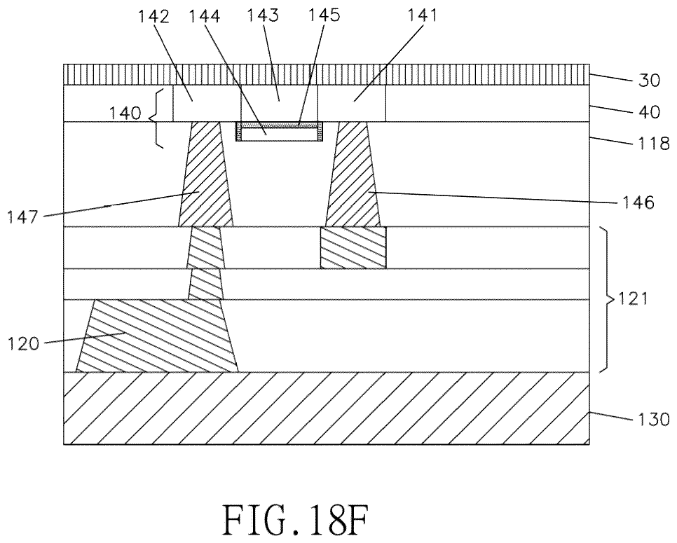

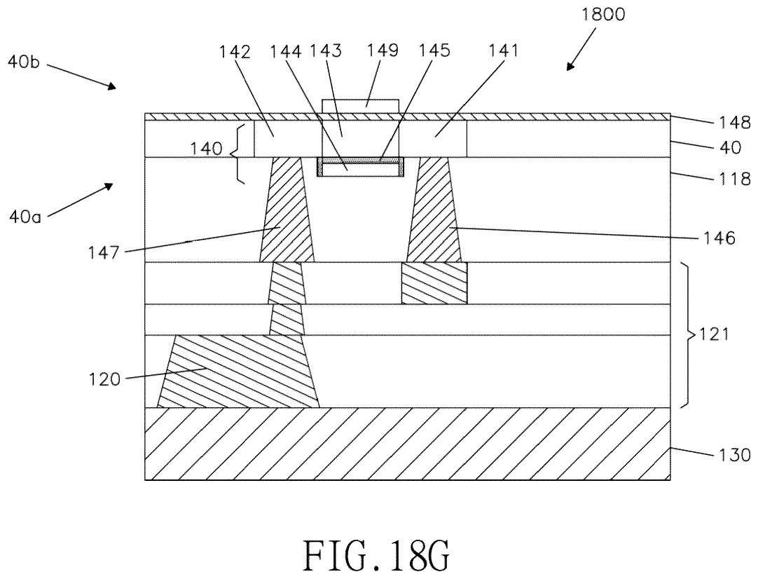

FIGS. 18A to 18G are schematic diagrams illustrating intermediate stages in the manufacture of a semiconductor device according to one embodiment of the present disclosure. With respect to FIGS. 18A to 18G, the steps are similar to that of described above with respect to FIGS. 13A to 13H and/or 15A to 15F except for the changes described herein.

As shown in FIG. 18A, a semiconductor structure 401 is provided (step (a)). The semiconductor structure 401 may be similar to the semiconductor structure 400 described above with regard to FIG. 4. In the embodiment shown in FIG. 18A, the semiconductor structure 401 comprises a first substrate 10, a second substrate 40 on the first substrate 10, a first bonding layer 20 between the first substrate 10 and the second substrate 40, a first etch stop layer 30 between the first bonding layer 20 and the second substrate 40, and a second etch stop layer 60 between the first substrate 10 and the first bonding layer 20. In one embodiment, the second etch stop layer has high etch selectivity against the first substrate 10. The second etch stop layer 60 may comprise silicon nitride, silicon oxynitride, doped semiconductor material, undoped semiconductor material, metal, conductive metal compound, or combinations thereof. All other descriptions about semiconductor structure 400 may apply here.

As shown in FIG. 18B, a first portion of the semiconductor device (FinFET 140) is formed (step (b)). The FinFET 140 may be similar to the FinFET 140 as shown in FIG. 13A where like reference numerals indicate like elements and may be formed using a method similar to that described above with respect to FIG. 13A. A first source/drain contact 146, a second source/drain contact 147, dielectric layers 18, first interconnect structures 120, and dielectric layers 121 similar to that of described above with respect to FIG. 13B may also be formed.

As shown in FIG. 18C, a third substrate 130 is added on the first side 40a of the second substrate 40 (step (c)). The addition of the third substrate 130 may be substantially similar to the processes described above with respect to FIGS. 12C and 13C, and the related description is omitted for brevity.

As shown in FIG. 18D, the first substrate 10 is removed to expose the second etch stop layer 60. The first substrate 10 can be removed by performing suitable process(es) such as grinding, chemical mechanical polishing (CMP), and etching process.

As shown in FIG. 18E, after the removal of the first substrate 10, the second etch stop layer 60 is removed to expose the first bonding layer 20. The second etch stop layer 60 may be removed by oxide etching, plasma etching, hydrogen peroxide etching, the like, or any suitable method. A third etching process may be performed by applying a third etchant to remove the second etch stop layer 60. In one embodiment, the second etch stop layer 60 comprising silicon nitride can be removed by applying a third etchant, e.g., hot phosphoric acid. However, the disclosure is not limited thereto.

As shown in FIG. 18F, the first bonding layer 20 is removed to expose the first etch stop layer 30. In one embodiment, the exposed first bonding layer 20 can be removed by grinding and/or CMP process, and the remained first bonding layer 20 can be removed by a first etching process. In the embodiment where the first bonding layer 20 comprises silicon oxide, the first etching process may be performed by applying a first etchant, e.g., dilute HF as previously described.

As shown in FIG. 18G, at least a portion of the first etch stop layer 30 is removed (step (e)), and a second portion of the semiconductor device is formed on the second side 40b of the second substrate 40 (step (f)). All other descriptions about the process described with respect to FIGS. 13E-13F may apply here if applicable. As such, a semiconductor device 1800 similar to the semiconductor device 1300, 1400, 1500, 1600 and/or 1700 described above is provided, where like reference numerals indicate like elements. In the process described herein, exposure of the second etch stop layer 60 may indicate an end of the removal of the first substrate 10, therefore, the introduce of the second etch stop layer 60 may result in a more controllable removal of the first substrate 10, which may render a more controllable removal of the first bonding layer 20. As such, manufacturing difficulties due to uneven removal and/or over-removal of the first substrate 10 and/or the first bonding layer 20 may be relieved.

FIG. 19 is a schematic diagram illustrating an intermediate stage in the manufacture of a semiconductor device according to one embodiment of the present disclosure.

As shown in FIG. 19, a semiconductor device 1900 is provided. The semiconductor device 1900 may be similar to the semiconductor device described above with regard to FIG. 13G where like reference numerals indicate like elements. The process for manufacturing semiconductor device 1900 may be substantially similar to the process described above with respect to FIGS. 13A to 13H. In the embodiment shown in FIG. 19, a second source/drain contact 147 may be formed on the second side 40b of the second substrate 40 after the removal of the first substrate 10 and the first bonding layer 20 and after the removal of the first etch stop layer 30. The second source/drain contact 147 is physically and electrically coupled to the second source/drain region 142 and is formed through one or more of the dielectric layers 119 and through the second gate dielectric 148. The second source/drain contact 147 may comprise similar materials as discussed above for the drain contact 117 and may be formed in the dielectric layers 119 using a damascene or dual damascene process or any suitable method. In the embodiment shown in FIG. 19, the second interconnect structures 122 are physically and electrically coupled to the second source/drain contact 147, as such, the second interconnect structures 122 can be electrically coupled to the first portion of the semiconductor device (e.g., the FinFET 140) through the second source/drain contact 147. In some embodiments, at least one of the first source/drain contact 146 and the second source/drain contact 147 or both of the first source/drain contact 146 and the second source/drain contact 147 may be formed on the second side 40b of the second substrate 40 and electrically coupled to the second interconnect structures 122. The process described herein may provide additional options for routing and may reduce the size of the circuit and/or improve the performance of the semiconductor devices.

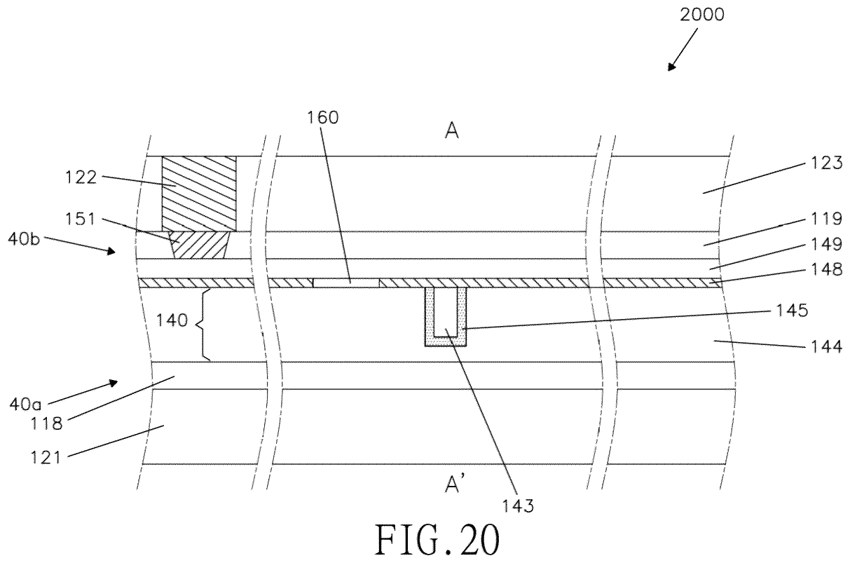

FIG. 20 is a schematic diagram illustrating an intermediate stage in the manufacture of a semiconductor device according to one embodiment of the present disclosure.

As shown in FIG. 20, a semiconductor device 2000 is provided. The semiconductor device 2000 may be similar to the semiconductor device described above with regard to FIG. 13G where like reference numerals indicate like elements. The process for manufacturing semiconductor device 2000 may be substantially similar to the process described above, for example, the process described in FIGS. 13A to 13H, FIG. 14, or FIGS. 15A to 15F. In the embodiment shown in FIG. 20, a via 160 may be formed on the second side 40b of the second substrate 40 after the removal of the first substrate 10 and the first bonding layer 20 and after the removal of at least a portion of the first etch stop layer 30. The via 160 is formed through the second gate dielectric 148. As discussed above with regard to FIGS. 13A to 13H. FIG. 14, and FIGS. 15A to 15F, in some embodiments, the second gate dielectric 148 may be a dielectric layer formed after the removal of the first etch stop layer; in some embodiments, the second gate dielectric 148 may include a layer of the first etch stop layer; and in some embodiments, the second gate dielectric 148 may include a portion of an intermediate layer, which is exposed after the removal of the first etch stop layer.

The via 160 is physically and electrically coupled to the first gate structure 144. The via 160 may comprise similar materials as discussed above for the drain contact 117 and may be formed in the second gate dielectric 148 using a damascene or dual damascene process or any suitable method. The second gate structure 149 may be formed using a method similar to that described above with reference to FIG. 13F and may be formed physically and electrically coupled to the via 160. As a result, the first gate structure 144 may be electrically connected to the second gate structure 149 through the via 160.

In the embodiment shown in FIG. 20, the second interconnect structures 122 are formed physically and electrically coupled to the second gate contact 151. As such, wiring for gate voltage can be disposed on the second side 40b of the second substrate 40, which may provide additional options for routing and may reduce the size of the circuit and/or improve the performance of the semiconductor devices. However, in other embodiments, instead of electrically coupling to the second interconnect structures 122 on the second side 40b of the second substrate 40, the first gate structure 144 may be electrically coupled to interconnect structures disposed on the first side 40a of the second substrate 40, e.g., interconnect structures similar to the first interconnect structures 120 shown in FIG. 13H.

The process described herein may provide a quasi-GAA (gate-all-around) FET, wherein both the first gate structure 144 and the second gate structure 149 are overlapped with the channel region 143 of the FinFET 140, and the first gate structure 144 and the second gate structure 149 collectively surround the channel region 143 of the FinFET 140 with four sides. The process described herein may provide manufacturing methods for a GAA-like FinFET structure which may be easy to perform. Moreover, by using an etch stop layer as described above, the complexity of the routing may be relieved, and the space required for metal lines may be reduced.

The semiconductor structures having an etch stop layer with high etch selectivity against the bonding layer and methods of manufacturing the same described above have one or more of the following advantages.

1. The semiconductor structures according to the present disclosure may comprise an etch stop layer between the bonding layer and the second substrate with high etch selectivity against the bonding layer. As such, the etch stop layer can protect the device element (e.g., a transistor, a diode, a capacitor, and a resistor), component(s) of a device element (e.g., a gate structure of a transistor, a dielectric layer of a transistor or a capacitor, or a conductive component of a capacitor), isolation structure (e.g., STI, oxide, etc.), and/or interconnect structures in the second substrate from the etching process. As such, the difficulty in fabricating semiconductor devices and/or interconnect structures on both sides of the second substrate may be reduced. The introduce of the etch stop layer can assure the planarity of the exposed surface of the second substrate and the etch stop layer may be used to monitor the etch endpoint.

2. The semiconductor structures according to the present disclosure may further comprise an alignment mark in the second substrate. As such, the introduce of the alignment mark may further reduce the difficulty in fabricating semiconductor devices or interconnect structures on both sides of the second substrate.

3. The semiconductor structures according to the present disclosure may include an intermediate layer between the etch stop layer and the second substrate. In some embodiments, the intermediate layer may be patterned. The patterned intermediate layer may provide routing and layout having better contact with the second substrate. In some embodiments, the intermediate layer of the semiconductor structures, which may comprise silicon oxide or high k material, may become a gate dielectric of a semiconductor device. The process disclosed herein may provide a gate dielectric made by desired material and having good contact with the second substrate and may reduce the difficulty of forming a high-quality gate dielectric on the substrate, especially on the second side of the substrate.

4. The semiconductor structures according to the present disclosure may further comprise a second etch stop layer between the first substrate and the bonding layer with high etch selectivity against the first substrate. In the process described herein, exposure of the second etch stop layer may indicate an end of the removal of the first substrate, therefore, the introduce of the second etch stop layer may result in a more controllable removal of the first substrate, which may render a more controllable removal of the first bonding layer. As such, manufacturing difficulties due to uneven removal and/or over-removal of the first substrate and/or the first bonding layer may be relieved.

5. The methods for making a semiconductor structure according to the present disclosure provide processes through which one skilled in the art can make the semiconductor structures as described above. As such, the semiconductor structures can be made cost-effectively.

6. The methods for making a semiconductor device according to the present disclosure may comprise forming a first portion of the semiconductor device, and removing at least a portion of the first etch stop layer. In some embodiments, the methods further comprise forming a second portion of the semiconductor device on a second side of the second substrate, in some embodiments, the first etch stop layer can be completely removed to expose the layer under the first etch stop layer (e.g., the second substrate or the intermediate layer). In some embodiments, the first etch stop layer can be partially removed by suitable methods such as photolithography and etching process to form trenches and/or openings exposing at least a portion of the second substrate or the intermediate layer. When the first etch stop layer comprises silicon oxide or high k material, at least a layer of the first etch stop layer may remain on the second substrate and the layer of the first etch stop layer may become a gate dielectric of a semiconductor device. As such, the first etch stop layer can be completely or partially removed depending on actual needs and properties of the materials.

7. The methods for making a semiconductor device according to the present disclosure provide processes through which fabrication of semiconductor devices and/or interconnect structures on both sides of the second substrate can be achieved. In one embodiment, the first portion of the semiconductor device on the first side of the second substrate comprises a transistor, and the second portion of the semiconductor device on the second side of the second substrate comprises a capacitor electrically coupled to a source region of the transistor. The semiconductor device may be a memory cell, including but not limited to a DRAM memory cell. In one embodiment, the first portion of the semiconductor device on the first side of the second substrate comprises a FinFET, and the second portion of the semiconductor device on the second side of the second substrate comprises a second gate structure. In some embodiments, the first interconnect structures on the first side of the second substrate and the second interconnect structures on the second side of the second substrate can be formed. In some embodiments, the first interconnect structures are electrically coupled to a first portion of the semiconductor device, and the second interconnect structures are electrically coupled to a second portion of the semiconductor device. In one embodiment, the first interconnect structures may also be electrically coupled to a second portion of the semiconductor device, and the second interconnect structures may also be electrically coupled to a first portion of the semiconductor device. In one embodiment, the first portion of the semiconductor device and the second portion of the semiconductor device can be electrically coupled by a via.

The foregoing description of embodiments is provided to enable any person skilled in the art to make and use the subject matter. Various modifications to these embodiments will be readily apparent to those skilled in the art, and the novel principles and subject matter disclosed herein may be applied to other embodiments without the use of the innovative faculty. The claimed subject matter set forth in the claims is not intended to be limited to the embodiments shown herein but is to be accorded the widest scope consistent with the principles and novel features disclosed herein. It is contemplated that additional embodiments are within the spirit and true scope of the disclosed subject matter. Thus, it is intended that the present invention covers modifications and variations that come within the scope of the appended claims and their equivalents.

1. A semiconductor structure, comprising:
a first substrate,
a second substrate on the first substrate,
a first bonding layer between the first substrate and the second substrate,
a first etch stop layer between the first bonding layer and the second substrate; and
wherein the first etch stop layer has high etch selectivity against the first bonding layer.

2. The semiconductor structure of claim 1, wherein the second substrate is made of silicon, germanium, silicon germanium, gallium arsenide (GaAs), indium phosphide (InP), silicon carbide (SiC), or gallium nitride (GaN).

3. The semiconductor structure of claim 1, wherein the first bonding layer comprises silicon oxide, and the first etch stop layer comprises silicon nitride, silicon oxynitride, doped semiconductor material, undoped semiconductor material, metal, or conductive metal compound.

4. The semiconductor structure of claim 1, wherein the first etch stop layer comprises a dielectric material.

5. The semiconductor structure of claim 1, wherein the first etch stop layer has an etch selectivity higher than 5:1 against the first bonding layer.

6. The semiconductor structure of claim 1 further comprising:
a second etch stop layer between the first substrate and the first bonding layer, wherein the second etch stop layer has high etch selectivity against the first substrate.

7. The semiconductor structure of claim 6, wherein the first substrate comprises single crystalline semiconductor material or glass, and the second etch stop layer comprises silicon nitride, silicon oxynitride, doped semiconductor material, undoped semiconductor material, metal, or conductive metal compound.

8. The semiconductor structure of claim 1 further comprising:
an intermediate layer between the first etch stop layer and the second substrate.

9. The semiconductor structure of claim 8, wherein the intermediate layer comprises doped semiconductor material, metal, or conductive metal compound.

10. The semiconductor structure of claim 9, wherein the first etch stop layer comprises silicon nitride or silicon oxynitride.

11. The semiconductor structure of claim 9, wherein the intermediate layer is patterned.

12. The semiconductor structure of claim 8, wherein the intermediate layer comprises silicon oxide or high k material.

13. The semiconductor structure of claim 12, wherein the first etch stop layer comprises silicon nitride, silicon oxynitride, doped semiconductor material, metal, or conductive metal compound.

14. The semiconductor structure of claim 1 further comprising an alignment mark disposed in the second substrate.

15. The semiconductor structure of claim 1 further comprising:
a second etch stop layer between the first substrate and the first bonding layer; and
a second bonding layer between the first substrate and the second etch stop layer, wherein the second etch stop layer has high etch selectivity against the second bonding layer.

16. The semiconductor structure of claim 15, wherein the second bonding layer comprises silicon oxide, and the second etch stop layer comprises silicon nitride, silicon oxynitride, doped semiconductor material, undoped semiconductor material, metal, or conductive metal compound.

17. A method for making a semiconductor structure, comprising:
(a) providing a first structure comprising a first substrate;
(b) providing a second structure comprising a second substrate and a first etch stop layer on the second substrate, wherein the second substrate comprises an implanted hydrogen layer;
(c) bonding the first structure and the second structure by a bonding layer to form a bonded structure, wherein the first etch stop layer has high etch selectivity against the bonding layer; and
(d) removing a portion of the second substrate from approximately the implanted hydrogen layer.

18. The method of claim 17, wherein the second substrate is made of silicon, germanium, silicon germanium, gallium arsenide (GaAs), indium phosphide (InP), silicon carbide (SiC), or gallium nitride (GaN).

19. The method of claim 17, wherein the bonding layer comprises silicon oxide, and the first etch stop layer comprises silicon nitride, silicon oxynitride, doped semiconductor material, undoped semiconductor material, metal, or conductive metal compound.

20. The method of claim 17, wherein the step (b) comprises:
(b1) providing the second substrate;
(b2) forming the first etch stop layer on the second substrate; and
(b3) implanting the hydrogen layer into the second substrate.

21. The method of claim 17, wherein the step (c) comprises forming a first dielectric layer on the first substrate and forming a second dielectric layer on the first etch stop layer before bonding.

22. The method of claim 17, wherein the bonded structure further comprises:
a second etch stop layer between the first substrate and the bonding layer.

23. The method of claim 22, wherein the step (a) comprises:
(a1) providing the first substrate; and
(a2) forming the second etch stop layer on the first substrate.

24. The method of claim 23, wherein the step (c) comprises forming a first dielectric layer on the second etch stop layer and forming a second dielectric layer on the first etch stop layer before bonding.

25. The method of claim 17, wherein the bonded structure further comprises:
an intermediate layer between the first etch stop layer and the second substrate.

26. The method of claim 25, wherein the step (b) comprises:
(b1) providing the second substrate;
(b2) forming the intermediate layer on the second substrate;
(b3) forming the first etch stop layer on the intermediate layer; and
(b4) implanting the hydrogen layer into the second substrate.

27. The method of claim 26, wherein the step (b2) further comprises patterning the intermediate layer.

28. A method for making a semiconductor device, comprising:
(a) providing a semiconductor structure comprising a first substrate, a second substrate on the first substrate, a bonding layer between the first substrate and the second substrate, and a first etch stop layer between the bonding layer and the second substrate, wherein the first etch stop layer has high etch selectivity against the bonding layer;
(b) forming a first portion of the semiconductor device;
(c) adding a third substrate on a first side of the second substrate, wherein the second substrate is between the third substrate and the first substrate;
(d) removing the first substrate and the bonding layer of the semiconductor structure to expose the first etch stop layer; and
(e) removing at least a portion of the first etch stop layer.

29. The method of claim 28, wherein the first portion of the semiconductor device comprises a transistor or a diode.

30. The method of claim 28, wherein the step (b) comprises doping the second substrate or etching the second substrate.

31. The method of claim 28 further comprising (f) forming a second portion of the semiconductor device on a second side of the second substrate.

32. The method of claim 31, wherein the first portion of the semiconductor device comprises a transistor comprising a source region, a drain region, a channel region, and a gate structure, and the second portion of the semiconductor device comprises a capacitor electrically connected to the source region of the transistor.

33. The method of claim 31, wherein the first portion of the semiconductor device comprises a transistor comprising a first source/drain region, a second source/drain region, a channel region, and a first gate structure, and the second portion of the semiconductor device comprises a second gate structure overlapped with the channel region of the transistor.

34. The method of claim 33 further comprising (g) forming a via on the second side of the second substrate, wherein the first gate structure is electrically connected to the second gate structure through the via.

35. The method of claim 28 further comprising forming first interconnect structures on the first side of the second substrate before the step (c).

36. The method of claim 28 further comprising forming second interconnect structures on a second side of the second substrate after the step (e).

37. The method of claim 28, wherein the semiconductor structure further comprises an intermediate layer between the first etch stop layer and the second substrate.

38. The method of claim 37, wherein the step (e) comprising removing at least a portion of the first etch stop layer to expose the intermediate layer.

39. The method of claim 37, wherein the intermediate layer is patterned.

40. The method of claim 28, wherein the step (d) comprises performing a first etching process by applying a first etchant.

41. The method of claim 28, wherein the step (e) comprises performing a second etching process by applying a second etchant.

42. The method of claim 28, wherein the semiconductor structure further comprises an alignment mark disposed in the second substrate.
